(19) United States
(12) Patent Application Publication
(10) Pub. No.: US 2026/0227267 A1
(43) Pub. Date: Aug. 6, 2026

(54) CHEMICAL SENSORS FOR LEAK DETECTION IN COOLING SYSTEMS

(71) Applicant: Nvidia Corporation, Santa Clara, CA (US)

(72) Inventors: William Andrew Mecham, Elk Grove, CA (US); Ryan Albright, Beaverton, OR (US); William Ryan Weese, Portland, OR (US); Benjamin Goska, Portland, OR (US); Aaron Carkin, Hillsboro, OR (US); Michael Thompson, Wilsonville, OR (US); Jordan Levy, Portland, OR (US)

(21) Appl. No.: 19/046,098

(22) Filed: Feb. 5, 2025

(51) Int. Cl. G01M 3/20; H05K 7/20

(52) U.S. Cl. CPC G01M 3/20; H05K 7/20627

(57) ABSTRACT

Systems and methods are directed a leak detection system that incorporates one or more chemical sensors to detect small quantities of leaks. The leak detection system may localized chemical sensors to detect leakage within a specific sub-volume of an enclosure. The one or more chemical sensors may be configured to detect an additive incorporated into cooling fluid.

### TECHNICAL FIELD

At least one embodiment pertains to monitoring cooling systems. More specifically, at least one embodiment pertains to electronic leak detection systems to detect small leaks within a designated area.

### BACKGROUND

Data centers may contain a number of compute units, which may be arranged in a variety of configurations, such as rack-mounted systems that include rows of racks that include a number of different sets of compute units. Compute units may be referred to as heat generating units within a data center and are often configured to run within a given temperature range. More compute-intense operations may generate more heat, which may be beyond the capabilities of air only cooling systems. As a result, data centers may incorporate liquid cooling systems, which may include cooling at a rack-level or at a chip-level, among other options. However, because compute units are sensitive electronic devices, leak detection is used to ensure that leaks can be quickly identified and isolated to reduce damage to electronic components. Typical leak detectors may be positioned within a rack and detect leaks at some threshold that provides sufficient liquid to wet a detector (e.g., physical contact with the leak), by which time the leak may be so severe that several electronic components are damaged.

### BRIEF DESCRIPTION OF THE DRAWINGS

Various embodiments in accordance with the present disclosure will be described with reference to the drawings, in which:

FIG. 1 illustrates an example data center cooling system, according to at least one embodiment;

FIG. 2A illustrates an example data center cooling system, according to at least one embodiment;

FIG. 2B illustrates rack-level features associated with a data center cooling system, according to at least one embodiment;

FIG. 2C illustrates rack-level features associated with a data center cooling system, according to at least one embodiment;

FIG. 3A illustrates an example representation of one or more chemical sensors associated with areas of interest within an enclosure, according to at least one embodiment;

FIG. 3B illustrates an example schematic representation of leak detection using a sensor assembly, according to at least one embodiment;

FIG. 3C illustrates an example schematic representation of a control system that may include one or more sensors, according to at least one embodiment;

FIG. 3D illustrates an example representation of leak detection within a target volume, according to at least one embodiment;

FIG. 3E illustrates an example graphical representation of a signal indicative of a leak, according to at least one embodiment;

FIG. 4A illustrates an example schematic representation of a sensor assembly, according to at least one embodiment;

FIG. 4B illustrates an example schematic representation of a differential analysis system for sets of sensor assemblies, according to at least one embodiment;

FIG. 4C illustrates an example schematic representation of a plurality of sensor assemblies and associated areas of interest, according to at least one embodiment;

FIG. 4D illustrates a schematic side view of an embodiment of leak detection in an enclosure, according to at least one embodiment;

FIG. 4E illustrates a schematic representation of a leak detection system, according to at least one embodiment;

FIG. 5A illustrates an example process for detecting a leak, according to at least one embodiment;

FIG. 5B illustrates an example process for supplementing additive in a cooling fluid volume, according to at least one embodiment;

FIG. 6 illustrates components of a distributed system that can be utilized to update or perform inferencing using a machine learning model, according to at least one embodiment;

FIG. 7 illustrates an example data center system, according to at least one embodiment;

FIG. 8 illustrates a computer system, according to at least one embodiment;

FIG. 9 illustrates a computer system, according to at least one embodiment;

FIG. 10 illustrates at least portions of a graphics processor, according to one or more embodiments;

FIG. 11 illustrates at least portions of a graphics processor, according to one or more embodiments;

FIG. 12 illustrates a computing system according to one or more embodiments; and

FIG. 13 illustrates a computing system according to one or more embodiments.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Approaches in accordance with various embodiments are directed toward one or more leak detection systems that may be used to detect small leaks (e.g., below a threshold quantity, less than used for in-tray moisture detectors, etc.) before the leaks are large enough to be detected with existing leak sensors. In at least one embodiment, systems and methods are directed toward injecting an additive into a cooling fluid that is detectable using one or more chemical sensors that may detect the presence of a molecule or compound within a volume of space. The one or more chemical sensors may be referred to as olfactory sensors, gas sensors, or sniffers, among other options. Embodiments of the present disclosure may be directed toward additive injection using one or more compounds or elements that may be detectable using the one or more chemical sensors without appreciably altering cooling characteristics of the cooling fluid. For example, the additives may not affect heat transfer capabilities above a threshold amount and/or may be added at a level that is below a quantity associated with corrosion. Systems and methods may deploy a variety of different chemical sensors and, moreover, the additive may be machine and/or human detectable. Non-limiting examples of gas detectors include electrochemical, catalytic, oxidative, semiconductive, photosensitive, infrared, ultrasonic, holographic and/or the like. In at least one embodiment, systems and methods include a number of chemical sensors that may be placed at a variety of different locations and coupled together at a central detection controller to identify a location for a leak. For example, sensors may be positioned at connections, at different tray locations, within enclosed hot isles, and/or combinations thereof. Furthermore, systems and methods may integrate additive injection and monitoring into the central control system to adjust levels of additive injection based on current operating conditions. Accordingly, embodiments may be deployed to detect minor leaks before the leaks are detectable by existing leak sensors to proactively schedule maintenance and/or downtime to address leaks.

One or more embodiments may be directed toward a leak detection system that may be used with a data center and/or an environment including one or more liquid cooling systems. The leak detection system may incorporate a plurality of sensors, which may be olfactory or chemical sensors, among other options, at individual connection locations for a liquid cooling system associated with an enclosure for one or more processing units. The liquid cooling system may be integrated into a larger cooling system, such as a cooling system for a data center, or may be localized, and may further be sealed or semi-sealed for a given rack or set of processing units. By way of example, an enclosure may have isolated cooling loops for different processing units and various embodiments may include additives that are injected into a particularized cooling loop to monitor leaks for that cooling loop. One or more sensors may further be arranged at different locations to facilitate detection of a leak location. For example, sensors may be arranged at certain locations associated with likely leak points, may be arranged at different inlet and outlet locations to determine a differential, and/or combinations thereof. In certain embodiments, sensors may be arranged within an enclosed or semi-enclosed space or volume for leak detection, such as by placing a fitting with a seal over a particular location. Various embodiments may further be configured to evaluate detected quantities of additives with respect to air flow through an enclosure, for example by one or more algorithms associated with one or more control systems.

One or more embodiments may be directed toward a leak detection system that includes one or more sensors that may also be referred to as “electronic noses.” The one or more sensors may be positioned within an enclosed space of a rack to detect leaks. However, as discussed herein, the enclosed space may not be a sealed space and may permit airflow, for example from one side to another. The one or more sensors may be chemical sensors positioned within a volume associated with a rack (e.g., processing unit rack, compute unit enclosure, etc.) to detect one or more compounds injected into a cooling fluid circulated through a cooling loop associated with one or more processing units of the processing unit rack. The processing unit rack refers to a framework or structure that houses multiple processing units—such as servers, processors, computing modules, or storage devices—within the data center, server room, or high-performance computing (HPC) environment. The leak detection system may also include one or more processing units to determine, based on a signal transmitted from at least one chemical sensor of the one or more chemical sensors responsive to detection of the one or more compounds. In at least one embodiment, the one or more compounds may be detected when a quantity of the one or more compounds exceeds a threshold level for the volume. For example, the threshold level may be associated with a precision of the one or more sensors and/or may be tuned as a percentage of the volume. In example embodiments, a quantity of the one or more compounds may exceed a threshold level for the volume of 10 parts per billion. In other example embodiments, the threshold level may be larger or smaller than example described herein. The one or more chemical sensors, along with the signal, may also be configured to transmit a location of the one or more chemical sensors, for example as an identification or other indicator with the sensor. The signal may then be used to infer a leak at a leak location. In at least one embodiment, the one or more chemical sensors may include at least one of an electrochemical sensor, a catalytic sensor, an oxidative sensor, a semiconductor sensor, a photosensitive sensor, an infrared sensor, an ultrasonic sensor, or a holographic sensor. The one or more chemical sensors may be associated with a data center and/or a rack that may be used to house different electronic components. In embodiments, the one or more sensors may be associated with a particular volume, which may correspond to at least one of a rack enclosure, a rack tray, a hot isle, or a cold isle. The volume may further be designated for a given sensor for a particular region within the volume. For example, within the volume of the rack or isle, each chemical sensor may be positioned to monitor a different sub-volume, where sub-volumes may overlap between sensors. As discussed herein, embodiments may use an additive injected into a cooling fluid associated with a liquid cooling system. The additive may include one or more compounds that are particularly selected to maintain a cooling capacity of the cooling fluid above a threshold limit. For example, the additives may include ultraviolet (UV) dyes, odorants (e.g., mercaptans, sulfates, etc.), and/or combinations thereof. When added to the liquid cooling system, a quantity of additive may be selected such that a likelihood of corrosion is less than a threshold or designated quantity. Furthermore, quantities of additive may also be based on properties of the overall system, such as an air flow rate circulating through the volume. In some embodiments, the additive comprised of one or more compounds may be non-corrosive at a concentration level at which the one or more compounds are injected into the cooling fluid. Embodiments of the present disclosure may select a quantity of additive such that a first detectable quantity of the one or more compounds is less than a second detectable quantity of the cooling fluid associated with one or more additional leak sensors associated with the volume. That is, embodiments may use chemical sensors that may detect leaks earlier than traditional methods, such as liquid sensors.

Systems and methods of the present disclosure may be directed toward a leak detection system that includes an enclosure to store one or more processing units in a plurality of racks, one or more chemical sensors to detect a threshold quantity of an additive within a volume of the enclosure, a cooling system to provide a cooling fluid to remove heat from the one or more processing units, with the cooling system including one or more cooling loops associated with individual racks of the plurality of racks, and a injection system to add a metered quantity of the additive to the cooling fluid. Additionally, the leak detection system may be used to identify one or more leaks via a control system that monitors and/or interprets signals received from the one or more chemical sensors. For example, the control system may identify one or more leaks associated with the one or more cooling loops based, at least in part, on a signal from at least one chemical sensor of the one or more chemical sensors associated with detection of the additive within the volume. The control system may further be used to determine a quantity of additive within a cooling fluid volume is below a threshold and then, responsive to the determination, add a supplemental quantity of additive to the cooling fluid volume. In this manner, embodiments may monitor for leaks using the one or more chemical sensors while also adjusting and tuning additive levels used for leak detection. For example, the leak detection system may incorporate an additive meter to monitor and detect additive levels within the cooling fluid and an injection system including an additive mover to inject the supplemental quantity of additive into the cooling fluid. As a result, when additive levels are low, the additive mover, such as a pump, may provide additional additives into the cooling fluid. In some embodiments, the additive comprised of one or more compounds may be non-corrosive at a concentration level at which the one or more compounds are injected into the cooling fluid. As discussed herein, the one or more chemical sensors used with the system may be at least one of an electrochemical sensor, a catalytic sensor, an oxidative sensor, a semiconductor sensor, a photosensitive sensor, an infrared sensor, an ultrasonic sensor, or a holographic sensor. Accordingly, the additive may be associated with different components that may be used with the selected sensors. Determinations for quantities of additive to add into the cooling system may be based on the threshold, which may be at least one of a mass of additive, a volume of additive, or a percentage of additive. Leak detection using the additive may include determining an air flow rate associated with the volume, determining a quantity of the signal, and determining a leak indicator based, at least in part, on the air flow rate and the quantity. As a nonlimiting example, the leak detection system may detect the presence of the additive within a certain volume, e.g., a server rack or server room. When the leak detection system detects the additive, the system assesses both the quantity of liquid present and the air flow rate within the volume. In some example embodiments, if the air flow rate is high—i.e., if air is moving rapidly through the volume where coolant has leaked—the air flow may carry vaporized coolant away from the source of the leak. Consequently, the leak detection system may not be able pinpoint the source of the leak with high specificity (e.g., down to the specific rack), and may instead provide a more general location of the leak (e.g., a specific section of a server room). In another nonlimiting example, if the leak detection system detects the presence of the additive but there is a low air flow rate within the volume, the leak detection system may determine a the source of the leak more easily than if the air flow rate was high (e.g., the leak detection system may pinpoint the leak to a specific server rack, or with even greater specificity). In example embodiments, an air flow rate may be measured in cubic feet per minute (CFM) or other suitable measurement such as 300 CFM, although in other embodiments the CFM may be any value.

One or more embodiments of the present disclosure may be directed toward a first leak detection sensor to detect an additive within a cooling fluid at a first threshold that is less than a second threshold associated with a second leak detection sensor configured to detect a quantity of cooling fluid. In at least one embodiment, each of the first leak detection sensor and the second leak detection sensor are associated with an enclosure to house one or more processing units and a cooling loop transporting the cooling fluid through the enclosure. The first leak detection sensor may be arranged at a connection associated with the cooling loop and the second leak detection sensor may be arranged within a drip tray axially lower than the connection. In one or more embodiments, the first leak detection sensor comprises at least one of an electrochemical sensor, a catalytic sensor, an oxidative sensor, a semiconductor sensor, a photosensitive sensor, an infrared sensor, an ultrasonic sensor, or a holographic sensor. Additionally, in at least one embodiment, the second leak detection sensor is a different type of leak detection sensor than the first leak detection sensor.

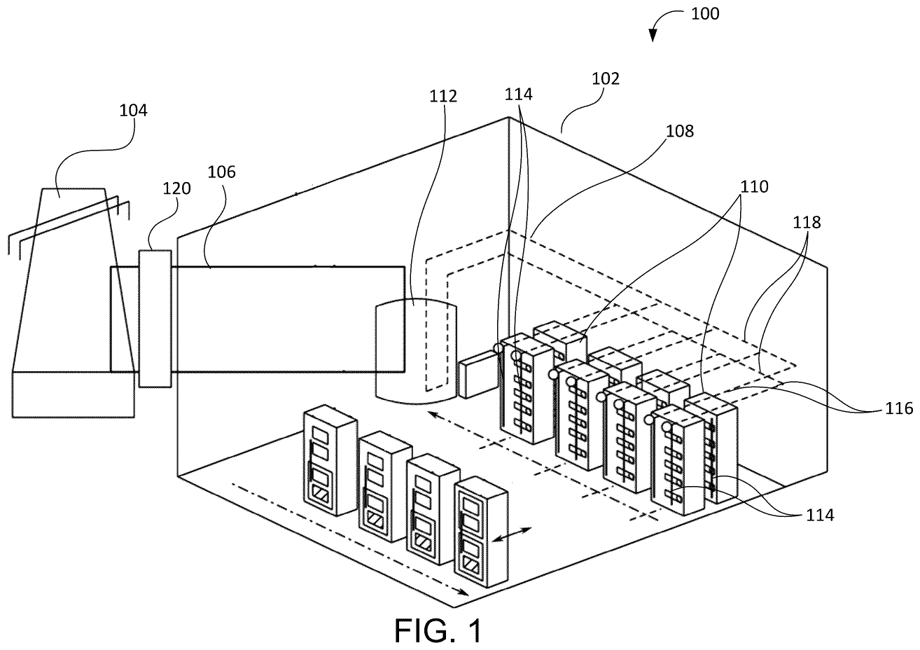

In at least one embodiment, a data center 100 can be utilized as illustrated in FIG. 1, which has a cooling system. In at least one embodiment, numerous specific details are set forth to provide a thorough understanding, but concepts herein may be practiced without one or more of these specific details. In at least one embodiment, data center cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a data center. In at least one embodiment, heat generated from these components, servers, and racks are cumulatively referred to as a heat feature or a cooling requirement as cooling requirement must address a heat feature entirely.

In at least one embodiment, a data center liquid cooling system is disclosed. In at least one embodiment, this data center cooling system addresses heat features in associated computing or data center devices, such as in Graphics Processing Unit (GPU)s, a Data Processing Unit (DPU), in switches, in dual inline memory module (DIMMs), or Central Processing Unit (CPU)s. In at least one embodiment, these components may be referred to herein as high heat density computing components. Furthermore, in at least one embodiment, an associated computing or data center device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature. Actions described herein may be performed by a processor (e.g., a central processing unit (CPU) or graphics processing unit (GPU)), data processing units (DPUs), quantum processing units (QPUs), a plurality of parallel processing units (PPUs), and application-specific integrated circuits (ASICs) memory module, or power supply. QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

In at least one embodiment, a liquid-cooled data center may have a stand-alone or a rack-mount chemistry sensor system as part of one or more sensors of a monitoring system. In at least one embodiment, such one or more sensors are able to perform continuous testing or monitoring of working fluids, such as cooling fluids or coolants that are either primary coolant, secondary coolant, or local coolant. In at least one embodiment, secondary coolant may be cooled by a primary coolant, whereas local coolant may be independently cooled or may also be cooled by a primary coolant. In at least one embodiment, upon a change in chemistry determined by at least one processor, additives may be provided for a coolant.

In at least one embodiment, local or other coolant readily available in a preloaded system may be mixed with secondary coolant as an additive. In at least one embodiment, a reservoir of available additives may be provided where such local coolant, primary coolant, secondary coolant, and additives are dispensed using one or more flow controllers. In at least one embodiment, additives may include inhibitors, biocide controls, and other such chemicals used to balance a chemistry of a working fluid, such as of primary coolant, secondary coolant, or local coolant (in itself). In at least one embodiment, such balancing enables optimized chemistry of a coolant within plumbing associated with a data center cooling system. In at least one embodiment, continuous monitoring and chemistry balancing enables a highly efficient operation in a data center cooling system. In at least one embodiment, such plumbing may include cooling distribution units (CDUs), cooling manifolds (or simply referred to as manifolds), tubes, pumps, joints, and cold plates. In at least one embodiment, such working fluid may be used to remove heat from an associated computing device, such as a GPU, a CPU, a switch, or from other components of a server.

In at least one embodiment, a data center 100 can be utilized as illustrated in FIG. 1, which has a cooling system subject to improvements described herein. In at least one embodiment, a data center 100 may be one or more rooms 102 having racks 110 and auxiliary equipment to house one or more servers on one or more server trays. In at least one embodiment, a data center 100 is supported by a cooling tower 104 located external to a data center 100. In at least one embodiment, a cooling tower 104 dissipates heat from within a data center 100 by acting on a primary cooling loop 106. In at least one embodiment, a cooling distribution unit (CDU) 112 is used between a primary cooling loop 106 and a second or secondary cooling loop 108 to enable absorption of heat from a second or secondary cooling loop 108 to a primary cooling loop 106. In at least one embodiment, a secondary cooling loop 108 can access various plumbing into a server tray as required, in an aspect. In at least one embodiment, cooling loops 106, 108 are illustrated as line drawings, but a person of ordinary skill would recognize that one or more plumbing features may be used. In at least one embodiment, flexible polyvinyl chloride (PVC) pipes may be used along with associated plumbing to move fluid along in each provided cooling loop 106, 108. In at least one embodiment, one or more coolant pumps may be used to maintain pressure differences within cooling loops 106, 108 to enable movement of coolant according to temperature sensors in various locations, including in a room, in one or more racks 110, and/or in server boxes or server trays within one or more racks 110.

In at least one embodiment, coolant the cooling fluid in a primary cooling loop 106 and in a secondary cooling loop 108 may be at least water and an additive. In at least one embodiment, an additive may be glycol or propylene glycol. The cooling fluid generally includes water, water solutions (e.g., propylene glycol-water), brine, antifreeze, a mixture of antifreeze and water, oil, alcohol, mercury or the like or any other suitable heat conductive fluid. The cooling fluid may be an electrically conductive cooling liquid and may include water, deionized water, or a coolant such as R-134a, a mixture of water and additives, such as a mixture of water and ethylene glycol or a mixture of water and propylene glycol e.g., a 25% concentration of propylene glycol in deionized water. The cooling fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the cooling fluid may be an absorption chiller having a working fluid being a mixed solution containing lithium bromide as the absorbent material and water as the carrier material. The cooling fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

In operation, in at least one embodiment, each of a primary and a secondary cooling loops may have their own cooling fluid. In at least one embodiment, cooling fluid in secondary cooling loops may be proprietary to requirements of components in a server tray or in associated racks 110. In at least one embodiment, a CDU 112 is capable of sophisticated control of coolants, independently or concurrently, within provided cooling loops 106, 108. In at least one embodiment, a CDU may be adapted to control flow rate of cooling fluid so that cooling fluid is appropriately distributed to absorbed heat generated within associated racks 110. In at least one embodiment, more flexible tubing of a row manifold 114 is provided from a secondary cooling loop 108 to enter each server tray to provide cooling fluid to electrical and/or computing components therein.

In at least one embodiment, tubing of a row manifold 118 that forms part of a secondary cooling loop 108 may be referred to as room manifolds. Separately, in at least one embodiment, further tubing 116 may extend from row manifold tubing 118 and may also be part of a secondary cooling loop 108 but may be referred to as row manifolds. In at least one embodiment, coolant tubing of a row manifold 114 enters racks as part of a secondary cooling loop 108 but may be referred to as rack cooling manifold within one or more racks. In at least one embodiment, row manifolds 116 extend to all racks along a row in a data center 100. In at least one embodiment, plumbing of a secondary cooling loop 108, including coolant tubing of row manifolds 118, 116, and 114 may be improved by at least one embodiment herein. In at least one embodiment, a chiller 120 may be provided in a primary cooling loop within data center 100 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 110 may be transferred to a cooling fluid exiting one or more racks 110 via flexible tubing of a row manifold 114 of a second cooling loop 108. In at least one embodiment, second cooling fluid (in a secondary cooling loop 108) from a CDU 112, for cooling provided racks 110, moves towards one or more racks 110 via provided tubing. In at least one embodiment, second cooling fluid from a CDU 112 passes from one side of a room manifold 118 having tubing, to one side of a rack 110 via a row manifold 116, and through one side of a server tray via different tubing of row manifold 114. In at least one embodiment, spent or returned second cooling fluid (or exiting second cooling fluid carrying heat from computing components) exits out of another side of a server tray (such as enter left side of a rack and exit right side of a rack for a server tray after looping through a server tray or through components on a server tray). In at least one embodiment, spent second cooling fluid that exits a server tray or a rack 110 comes out of different side (such as exiting side) of tubing of row manifold 114 and moves to a parallel, but also exiting side of a row manifold 116. In at least one embodiment, from a row manifold 116, spent second cooling fluid moves in a parallel portion of a room manifold 118 and is going in an opposite direction than incoming second cooling fluid (which may also be renewed second cooling fluid), and towards a CDU 112.

In at least one embodiment, spent second cooling fluid exchanges its heat with a primary cooling fluid in a primary cooling loop 106 via a CDU 112. In at least one embodiment, spent second cooling fluid may be renewed (such as relatively cooled when compared to a temperature at a spent second cooling fluid stage) and ready to be cycled back to through a second cooling loop 108 to one or more computing components. In at least one embodiment, various flow and temperature control features in a CDU 112 enable control of heat exchanged from spent second cooling fluid or flow of second cooling fluid in and out of a CDU 112. In at least one embodiment, a CDU 112 may be also able to control a flow of primary cooling fluid in primary cooling loop 106.

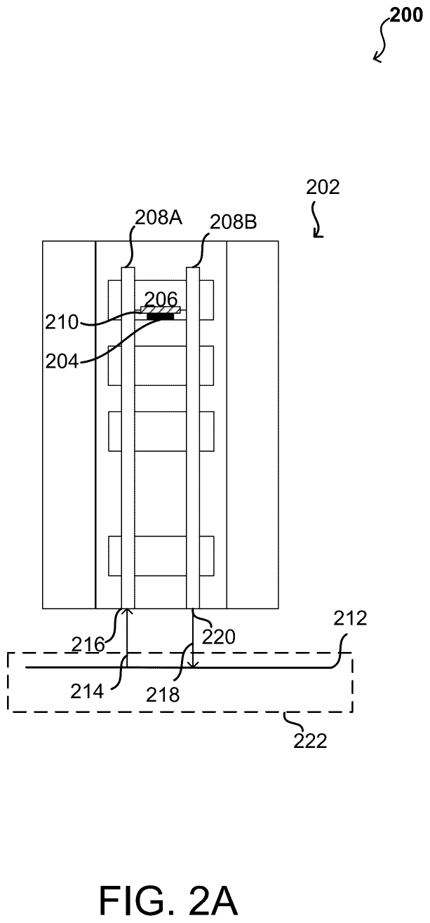

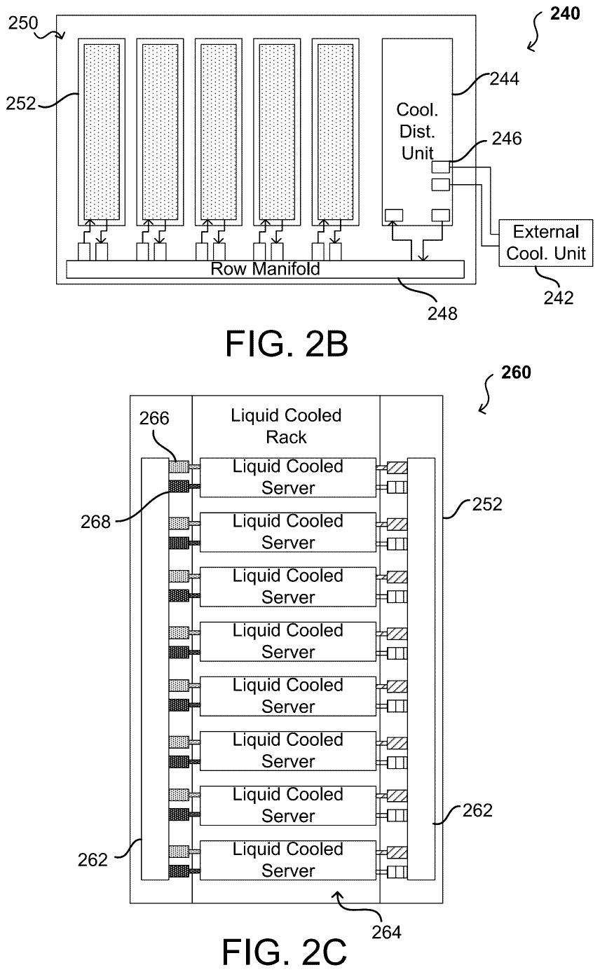

FIG. 2A illustrates an example environment 200 that may be used with embodiments of the present disclosure to provide cooling fluid to one or more computing devices. In this example, a rack 202 is used to house a number of computing devices 204 (e.g., servers, processing units, etc.) in a stacked configuration. The configuration of FIG. 2A may be referred to as showing “rack-level features” for cooling one or more computing devices 204, but embodiments of the present disclosure are not limited to only rack-level cooling and may be expanded to other cooling configurations and arrangements.

The illustrated rack 202 includes a number of shelves 206 that may hold one or more computing devices 204. Each of these shelves 206, and/or the computing devices 204 associated with the shelves 206, may be associated with manifolds 208, which may include an inlet manifold 208A (e.g., a supply manifold) and an outlet manifold 208B (e.g., a return manifold), to provide a cooling fluid to dissipate heat away from the one or more computing devices 204 and then to carry heated fluid away from the one or more computing devices 204. In this example, the manifolds 208 may be coupled to one or more heat plates 210 associated with the one or more computing devices 204, for example via tubing or the like. As discussed herein, the tubing may include plastic tubing, metallic tubing, composite tubing, and/or combinations thereof.

The shelves 206 may also include a variety of different sensors, which may be mounted within the shelf. For example, fluid detectors, such as ribbon detectors, may be positioned within the shelves 206 to detect leaks associated with a cooling fluid system 222. However, these sensors often need a threshold amount of liquid prior to obtaining a signal indicative of a leak. Often, by the time the leak is detected, damage is significant and/or may lead to a sudden preventative action, instead of proactively identifying leaks and then scheduling maintenance. Embodiments of the present disclosure may address and overcome this problem by detecting leaks sooner and at smaller quantities of leaked fluid.

While the illustrated example includes a single inlet manifold 208A and a single outlet manifold 208B, various embodiments may include more manifolds 208 and the manifolds may be arranged at different locations. For example, the manifolds 208 may be arranged at sides of the rack 202 to provide improved access to the interior of the rack, such as the shelves 206. Additionally, in at least one embodiment, the manifolds 208A, 208B may be positioned on opposite sides of the rack 202. Furthermore, embodiments may include multiple manifolds 208, with particular manifolds being used to direct fluid to/from particular shelves 206. Accordingly, a variety of configurations for cooling manifolds may be used within the scope of the present disclosure.

The manifolds 208 are shown coupled to a row manifold 212, which may be part of a secondary cooling loop. The row manifold 212 may include both an “inlet” line that carries cool fluid toward the shelves 206 and an “outlet” line that carries heated fluid away from the shelves 206. The row manifold 212 may include a connection 214 to a source inlet 216 of the manifold 208A and a connection 218 to a source outlet 220. The source inlet 216 may carry the cooled fluid along a length of the manifold to one or more outlets that may direct the cooled fluid toward the heat plates 210. The heat plates 210 may then include different connections to inlets of the manifold 208B that may direct heated fluid to the source outlet 220 to return to the row manifold 212 so that heated fluid may be cooled and then reused. As discussed herein, the row manifold 212 may be part of one or more cooling fluid systems 222, which may include components discussed, for example, in FIG. 1.

FIG. 2B illustrates a system 240 that may be used with embodiments of the present disclosure. The illustrated system 240 may include various features discussed with reference to FIG. 2A and herein, such an external cooling unit 242, such as a cooling tower, which may be part of an overall data center cooling system. This example illustrates the external cooling unit 242 coupled to a cooling distribution unit 244, which may be for a data center as a whole, or in certain embodiments, may be a localized cooling distribution unit at a rack or row level, among other options. The illustrated cooling distribution unit 244 may include a control board 246 to receive data from a variety of sensors associated with the cooling system. For example, the one or more sensors may provide coolant flow rate data, cooling pressure data, status of auxiliary systems, and/or the like.

The illustrated embodiment includes a row manifold 248 that sends/receives cooling fluid to/from the cooling distribution unit 244. The row manifold 248 also distributes and receives cooling fluid from a row 250 of racks 252, which in this example are liquid cooled racks. In at least one embodiment, there can be different levels of flow into, and out of, different liquid cooled racks. Additionally, there may also be different flows into individual servers in a rack. As discussed herein, systems and methods of the present disclosure may be used to form one or more portions of the row manifold 248 and/or may be used as part of a rack-specific manifold, as discussed herein.

FIG. 2C illustrates a system 260 that may be used with embodiments of the present disclosure. This example system includes the rack 252 with rack-level manifolds 262. As shown, the rack 252 includes a number of liquid cooled servers 264 or other such devices. In at least one embodiment, the rack-level manifold 262 provides a flow of liquid into each liquid cooled server 264 through an inlet valve 266, and return liquid with heat removed from that liquid cooled server 264 through an outlet valve 268. In at least one embodiment, sensors can capture information about temperature, fluid flow, or other such aspects of a computing environment internal and/or external to the rack 252, including internal and/or external to any individual liquid cooled servers 264 located therein. Fluid associated with the rack-level manifold 262 may be used to remove an amount of heat from liquid cooled servers 264, but due to factors such as varying load and external temperature fluctuations, temperatures at various locations may change, and may reach or exceed temperature limits at which these devices can continue to operate correctly. In at least one embodiment, an attempt can be made to ensure that temperatures at specific locations remain below an acceptable limit, where those locations may relate to junction temperatures or core temperatures for a processor (e.g., a CPU or GPU), memory module, or power supply.

In at least one embodiment, fluid quality is monitored and controlled at a rack level using one or more assemblies or sensors, for example inline flow sensors that can be associated with the rack-level manifold 262 as a whole and/or for individual liquid cooled servers 264. Different racks and servers may have different flow characteristics, such as different diameter flow channels in direct-to-chip cooling boards, and as a result, different cooling configurations, different manifold sizes, and/or different manifold properties may be used.

Systems and methods of the present disclosure address and overcome problems with existing leak detection systems that may have limited detection capabilities with respect to a minimum or threshold quantity of detectable fluid. One challenge with leak detection is detecting leaks quickly to enable rapid remediation before damage occurs to sensitive electronic components. The problems of slow detection may be exacerbated in dense racks where more electronic components are packed into smaller spaces, resulting in dripping liquid possibly spreading to other equipment, such as by the associated fans of the components. While many cooling systems add UV dyes for manual leak inspection, the manual inspections are often delayed until after a threshold quantity of liquid is detected by other sensors. As a result, the UV dye is used for reactive leak detection based on another signal instead of proactive detection prior to large problems, as performed by embodiments of the present disclosure. Embodiments address and overcome these problems, among others, by incorporating one or more chemical sensors configured to detect a presence of an extra additive included in a chosen cooling liquid. The additive may be detectable in small quantities (e.g., less than the quantity for a ribbon liquid detector) while also not materially affecting the thermal specifications of the cooling loop liquid. Embodiments are directed toward proactive leak detection to determine a presence of leaks before other detectors, such as moisture sensors, which often do not detect leaks until a threshold quantity of fluid has accumulated, which often leads to damage of various components. One or more embodiments may be directed toward additives with olfactory characteristics that permit detection by a human or chemical sensor. When presence of the additive surpasses a designated threshold, an alert may be triggered to appropriate personnel to respond and take action as needed. Accordingly, systems and methods may be used to monitor leaks within data centers or other electronic liquid cooling applications.

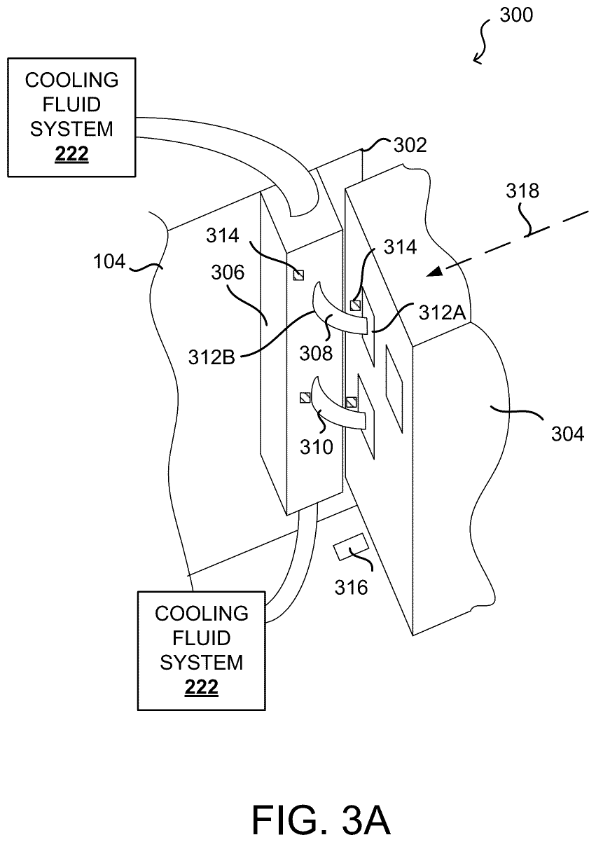

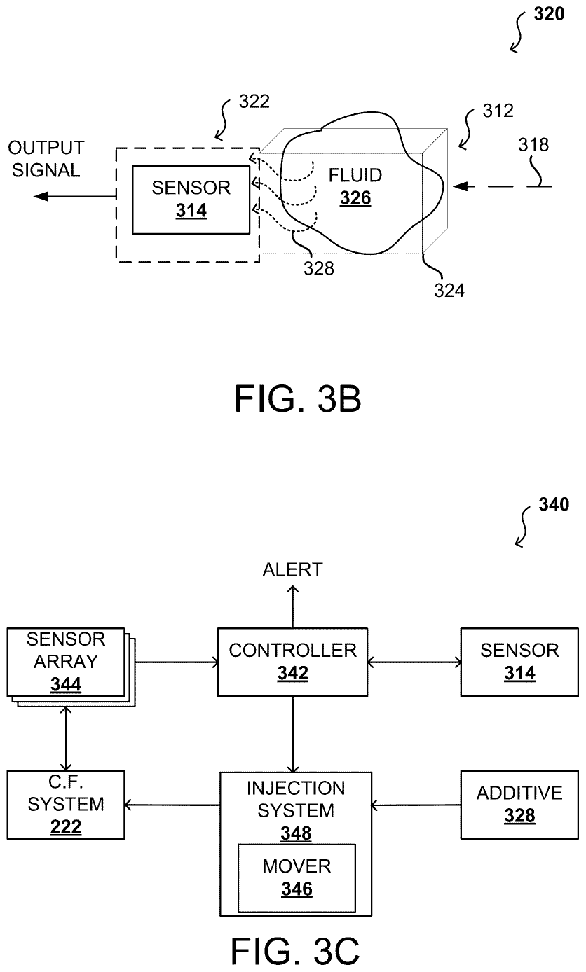

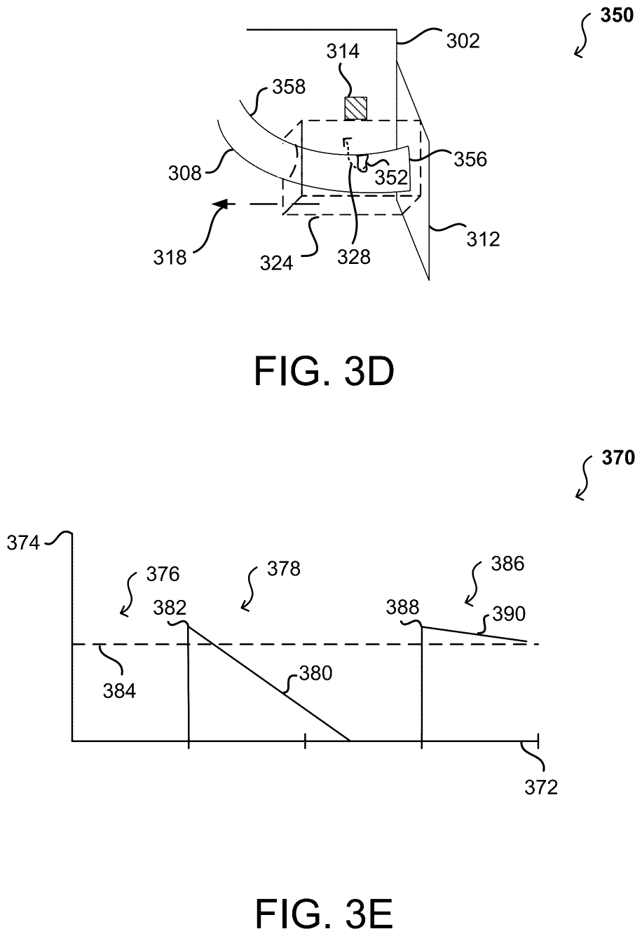

FIG. 3A illustrates a schematic representation of an environment 300 that may use embodiments of the present disclosure. In this example, an enclosure 302 includes an electronic component 304, such as a server unit, which may include a number of different electronic components and/or heat-generating units, as discussed herein. The enclosure 302 in this example is used for liquid cooling operations and includes a manifold 306 with inlet and outlet flow paths 308, 310, which may form a cooling loop. The illustrated manifold is part of the cooling fluid system 222, which may include one or more cooling loops, as discussed herein. The flow paths 308, 310 may be coupled to the manifold 306 and/or the electronic component 304 at different areas of interest 312, such as connecting locations which may be more susceptible to leakage than other locations. Embodiments of the present disclosure may be used to monitor one or more areas of interest 312 for fluid leaks. In at least one embodiment, one or more sensors 314 (e.g., chemical sensors, leak detection sensors, sensor elements, sensor assemblies, etc.) may be used to monitor a particular area of interest 312. The area of interest 312 may be associated with one or more volumes of space within a detectable region of the one or more sensors 314.

Systems and methods may provide monitoring and identification of leak locations prior to existing sensor configurations, such as the sensor array 316, which may be operational with larger threshold levels of fluid prior to identifying a leak. By the time sufficient fluid collects at the sensor array 316, there may be significant damage to the electronic component 304. In contrast, systems and methods of the present disclosure may be used to identify smaller quantities of fluid, for example due to one or more additives within the fluid, in order to provide improved monitoring and remediation capabilities.

In at least one embodiment, the one or more sensors 314 may be associated with olfactory sensors that detect a compound or element within a volume of space. A quantity of additive may be selected for detection based, at least in part, on an airflow 318 through the enclosure 302. For example, the enclosure 302 may be associated with one or both of an air cooling system and the cooling fluid system 222. As a result, air may circulate through the enclosure 302 to dissipate heat away from the electronic component 304, for example by being drawn from a cold isle and then exhausting into a hot isle. Various embodiments of the present disclosure may be directed toward volumes around a given connection or area of interest 312 and may be spaced and tuned to detect the additive in the presence of the circulating airflow 318.

FIG. 3B illustrates an example schematic representation 320 that may be used with embodiments of the present disclosure. This illustrated example includes the sensor 314, which may be from a portion of a sensor assembly 322. By way of example, the sensor assembly 322 may include additional components such as a power supply, communication device, and/or the like, as discussed herein. In operation, the sensor assembly 322 and associated sensor 314 may be positioned proximate an area of interest 312, such as a connection between a cooling loop and an electronic component, among other options. The area of interest 312 may be associated with a volume 324 (e.g., detectable volume, sensing volume, target volume, etc.) that may correspond to a region of sensing capability for the sensor 314. For example, the volume 324 may be a certain portion that is within a sensitivity or range of the sensor 314.

In one example, fluid 326 may leak from a connection and may include an additive 328 that may be sensed or detected by the sensor 314. As one non-limiting example, the additive 328 may be an odorant and the sensor 314 may be configured to detect presence of the chemicals and/or compounds of the odorant. Additionally, as discussed herein, use of the odorant may also permit a human operator, such as one walking through a data center, to also detect leaks. The sensor 314 may detect the presence of the additive 328 and may, in certain embodiments, include logic to determine whether or not a threshold quantity of additive 328 is detected. However, in other examples, the presence of the additive 328 may produce an output signal that is evaluated by one or more downstream controllers. For example, one or more properties of the output signal may be proportionate to the amount of additive 328 detected by the sensor 314, and as a result, the controller may be used to determine whether or not the quantity of additive exceeds one or more thresholds.

FIG. 3C illustrates an example schematic representation of a leak detection system 340 that may be used with embodiments of the present disclosure. One or more embodiments may use a controller 342, which may be a central controller associated with an overall data center cooling system and/or a controller particularly associated with the leak detection system 340, to monitor and supplement additive 328 being included within the cooling fluid system 222 and/or to generate alerts or signals responsive to information from the sensor 314. One or more sensor arrays 344 may be used to monitor properties of the cooling fluid system 222 and/or portions thereof, such as different cooling loops. The one or more sensor arrays 344 may include sensors to detect a quantity of additive 328 present within the cooling fluid system 222. For example, a target detectable quantity may be added to the system, which may be based on a volumetric quantity, a mass quantity, and/or the like. Signals from the one or more sensor arrays 344 may be used by the controller 342 to control addition of the additive 328 to the cooling fluid system 222, for example using an injection system 348 including one or more additive movers 346, which may include pumps or the like. In operation, if the detected quantities of additive 328 within the cooling fluid system 222, or portions thereof, fall below a target, the controller 342, using information from the one or more sensor arrays 344, may provide a signal to the injection system 348 additive mover 346 to add additional additive 328 into the cooling fluid system 222. In this manner, the leak detection system 340 may maintain a detectable quantity of additive for the sensors 314.

FIG. 3D illustrates an example representation 350 of the sensor 314 positioned proximate to the area of interest 312 to detect leaks within a connection, which in this example is a fluid connection associated with the flow path 308. In at least one embodiment, sensors 314 may be positioned with respect to the area of interest 312 to detect leaks within the volume 324, which is schematically represented as dashed lines. The illustration of the volume 324 as a rectangle is by way of non-limiting example only and is intended to provide a visual representation of sensing area, but not intended to limit the volume 324 to a particular size or shape.

In at least one embodiment, the volume 324 corresponds to an area within which the sensor 314 may detect the additive 328 by a threshold level while accounting for air circulation through the volume 324 due to the airflow 318, represented by the dashed arrow. As discussed, one or more embodiments may include enclosures that may use both liquid and air cooling, and the air cooling may include the airflow 318 from a cold isle to a hot isle, with the airflow 318 removing heat from the electronic component 304. As a result, the airflow 318 may remove or displace the additive 328 associated with a leak 352 formed in the flow path 308. Embodiments of the present disclosure may provide sufficient quantities of additive 328, which may be based on properties of the airflow 318, so that the leak 352 is detectable by the sensor 314.

As shown, the leak 352 may form on tubing 354 of the flow path 308 and/or at one or more connections 356, among various other options. In this example, the leak 352 may be a small leak that, for example, would not produce a quantity of liquid sufficient to active one or more other sensor arrays, such as traditional moisture sensors. Embodiments of the present disclosure may use the one or more sensors 314 to identify the additive 328 as an odorant or other gaseous or chemical method. For example, the one or more sensors 314 may be configured to detect a particular chemical composition associated with the additive 328 and, upon detecting the composition, may provide one or more signals and/or alerts to a controller, among other options. In this manner, leaks 352 may be detected at an early stage to enable proactive identification and repair.

FIG. 3E illustrates a graphical representation of a signal response 370 that may be used with embodiments of the present disclosure. In this example, the x-axis 372 is associated with time and the y-axis 374 is associated with a signal value. As discussed herein, the signal value may correspond to a determination that a particular compound or element is present within a detectable volume. In certain embodiments, the signal may be processed and be associated with an output alarm. In certain embodiments, the signal may be an output voltage or current that is proportional to, or weighted, based on a quantity of compound or element detected by the sensor 314. The example representation illustrates a configuration where the signal response is associated with an output voltage responsive to a quantity of additive detected.

In a first region 376 there is no signal, indicative of a lack of additive being detected by the sensor 314. The lack of additive detection may be inferred to be an absence of a leak in at least one embodiment. However, in a second region 378, a signal response 380 is illustrated, which has a peak 382 that exceeds a threshold 384, which may be a tuned value that corresponds to detection of a leak. For example, the threshold 384 may be lower in highly sensitive environments or if an earlier leak detection is desired with the potential for a greater number of potential false positives. As shown in the second region 378, the signal response 380 decreases linearly, by way of non-limiting example, which may be indicative of the air flow displacing the air within the detectable volume, and as a result, also displacing the additive 328. Various embodiments of the present disclosure may determine whether or not to trigger an alarm or signal based on factors such as a duration the signal remains above the threshold 384, a number of signals above the threshold 384 over a period of time, and/or combinations thereof. For example, a single peak that exceeds the threshold 384 may be sufficient to generate an alarm indicative of a leak.

A third region 386 illustrates a second peak 388 associated with a second signal response 390. In this example, the signal response 390 also decreases linearly, as a non-limiting example, but is maintained above the threshold 384 for a longer period of time than in the second region 378. As discussed, the duration of time the signal remains above the threshold 384 may be a factor in determining whether to trigger an alarm, or some other action, responsive to detection by the sensor 314.

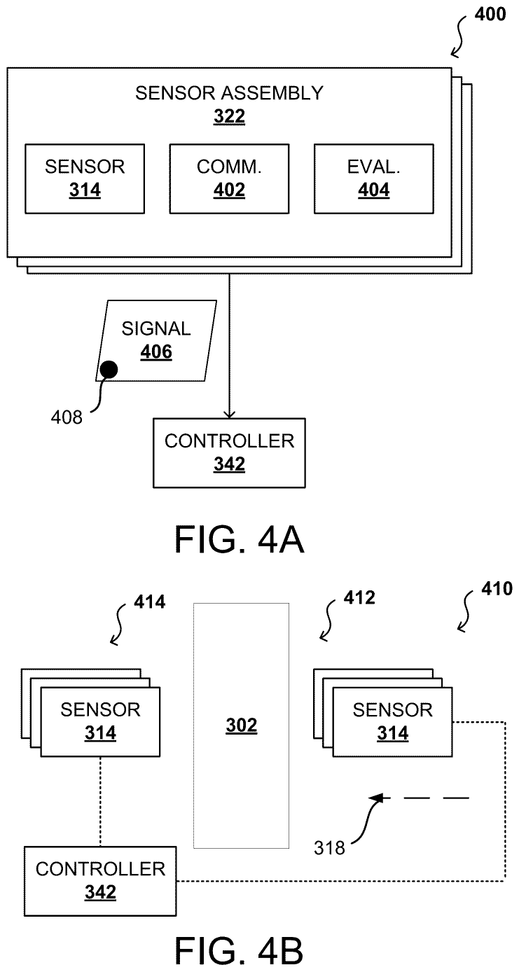

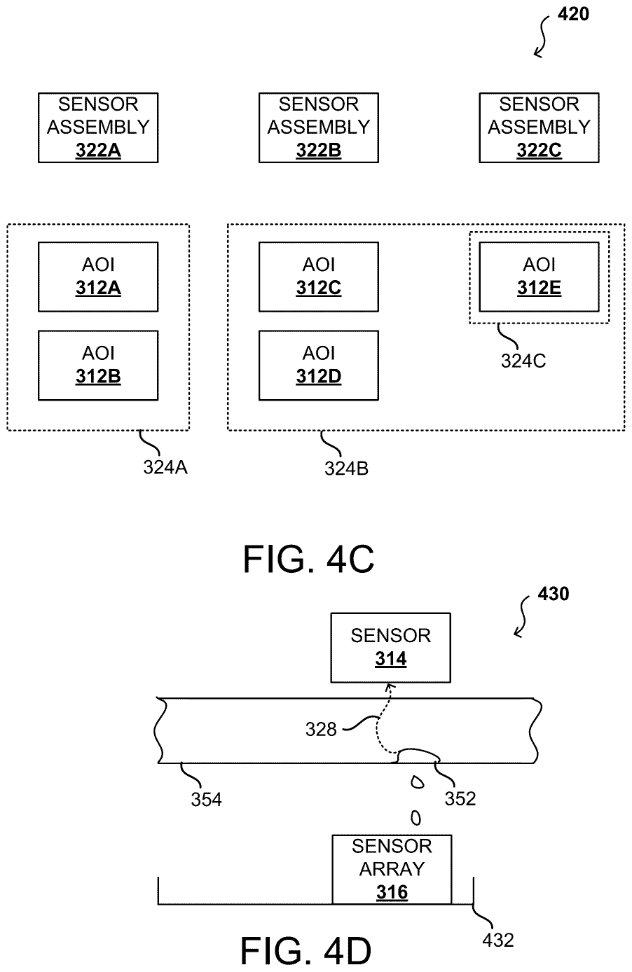

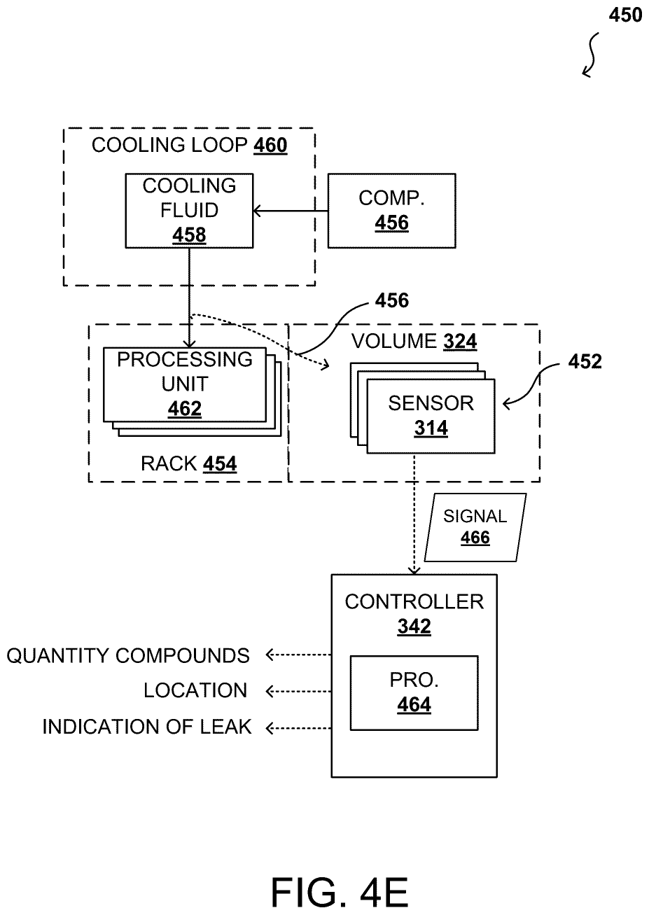

FIG. 4A illustrates an example schematic representation 400 of a plurality of sensor assemblies 322 that may be used with embodiments of the present disclosure. In this example, the sensor assemblies 322 include sub-components including the sensor 314, a communication system 402, and an evaluation engine 404. The sensor 314, as discussed herein, may include one or more sensors that may be used to detect a chemical compound or element within an area of interest, such as a volume of air, and may include a variety of different sensors 314 including, as one non-limiting example, olfactory sensors. The communication system 402 may be used to transmit data to the controller 342. The communication system 402 may include a wired connection, a wireless connection, or combinations thereof. For example, a low-energy wireless connection, such as a Bluetooth connection, may be used to transmit information to the controller 342 and/or one or more associated controllers or sub-controllers that may monitor one or more aspects of the cooling fluid system. For example, an individual controller may be associated with an enclosure or a row and the individual controller may be used to feed into an overall control system for the data center.

Further illustrated with the sensor assembly 322 is onboard logic in the form or an evaluation engine 404, which may be used to perform processing and/or pre-processing of information received by the sensor 314. For example, the evaluation engine 404 may be used to evaluate one or more output signals from the sensor 314 to determine whether the one or more output signals correspond to a leak. In at least one embodiment, the evaluation engine 404 may execute on a processor associated with stored instructions on a memory, as discussed herein, and may be tuned for different operating conditions or parameters. As a result, one set of senor assemblies 322 for a first rack or enclosure may operate using different conditions than another set of sensor assemblies 322 for the same rack/enclosure and/or a different rack/enclosure. The evaluation engine 404, for example, may convert an input voltage signal provided by the sensor 314 into a determination with respect to a leak. Various embodiments may also omit the evaluation engine 404 from one or more sensor assemblies 322 and evaluation may be done at the controller 342.

In operation, one or more output signals 406 are transmitted to the controller 342 via the communication system 402. As discussed herein, the one or more output signals 406 may correspond to a value indicative of information received by the sensor 314, which may be processed by the controller 342. Furthermore, in one or more embodiments, the output signal 406 may correspond to an alarm or a processed signal, such as one produced after evaluation by the evaluation engine 404. The illustrated output signal 406 also includes an identification 408, which may be used to determine a source of the output signal 406 (e.g., determine a particular sensor assembly 322 sending the output signal 406). In this manner, the identification 408 may be used to link the signal to a certain sensor assembly 322, which may further be correlated to a particular location within the data center, to identify the area associated with the signal. Accordingly, systems and methods may be used to identify and provide locations for leaks. Such a system may be deployed in a data center, where there may be thousands of potential leak points. By including the identification 408, particular regions can be quickly identified for remediation.

FIG. 4B illustrates an example schematic representation 410 that may be used with embodiments of the present disclosure. In this example, differential sensors 314 are illustrated at an upstream 412 and a downstream 414 side of the enclosure 302. The upstream and downstream sides 412, 414 refer to the direction of flow of the airflow 318, which is shown moving from a cold isle into the enclosure and then exhausting into a hot isle, as discussed herein. In at least one embodiment, different sets of sensors 314 may be positioned on the upstream 412 and downstream 414 sides in order to determine whether one or more readings indicative of a leak are due to leaks within the enclosure 302 or are associated with one or more environmental conditions within the data center. For example, a leak within a manifold external to the enclosure 302 may carry additives into the enclosure 302 with the airflow 318, which may then provide a signal associated with a leak. However, while identifications of leaks are advantageous within the data center, particular sensors 314 may be associated with particular locations, and as a result, a sensor may inadvertently direct an operator to an incorrect location to identify leaks. Accordingly, one or more embodiments may be used to evaluate signals from the different sets of sensors 314 to determine whether a differential reading exceeds one or more thresholds. For example, if a reading is present at a sensor in the upstream side 412 but not at the downstream side 414, the controller 342 may be used to determine that the leak is associated with an external leak originating outside of the enclosure 302. In contrast, readings at each of the upstream and downstream sides 412, 414 may be indicative of a leak within the enclosure 302.

FIG. 4C illustrates an example representation 420 of volumes 324 for different sensor assemblies 322. In this configuration, the sensor assembly 322A is positioned to detect additives 328 within the volume 324A that encompasses both the first area of interest (AOI) 312A and the second AOI 312B. In one or more embodiments, AOIs may be different connections or tubes, among other options. As shown, neither of the sensor assembly 322B nor the sensor assembly 322C include the first or second AOIs 312A, 312B within their respective volumes 324B, 324C. However, in this example, the volume 324B overlaps with the volume 324C. For example, the volume 324B may correspond to the sensor assembly 322B and includes each of the AOIs 312C-312E. In contrast, the volume 324C only includes the AOI 312E. Accordingly, systems and methods may deploy different configurations of sensor assemblies to monitor different AOIs, which may include different overlapping regions for important areas and/or may include different overlapping regions for different sensor modalities in order to provide redundant checks for important regions.

FIG. 4D illustrates a schematic representation 430 for leak detection that may be used with embodiments of the present disclosure. In this example, a tubing 354 includes the leak 352 that is dripping onto the sensor array 316 within a drip tray 432. The leak 352 is also emitting the additive 328 for sensing by the sensor 314. In operation, a quantity of fluid from the leak 352 to activate the sensor array 316 may be so large that damage will occur to various components prior to receiving the notification. Embodiments of the present disclosure address and overcome these problems by providing an earlier warning due to the detection of small amounts of additive 328 that may be released at early stages of the leak 352. In this manner, leak detection may be more proactive to quickly identify leaks prior to damage to sensitive components.

FIG. 4E illustrates a schematic representation 450 of an example of a leak detection system that may be used with embodiments of the present disclosure. The illustrated example includes a set 452 of chemical sensors 314 to be positioned within the volume 324 associated with a processing unit rack 454. As shown, the set 452 of chemical sensors 314 are positioned to detect one or more compounds 456, which may be associated with the additive 328, injected into a cooling fluid 458 circulated through a cooling loop 460 associated with one or more processing units 462 of the processing unit rack 454. This example also includes a processor 464, such as a processor that is part of the controller 342. The processor 464, in at least one embodiment, may include circuitry discussed herein, that may be used to determine, based on a signal 466 transmitted from one or more chemical sensors 314 of the set 452 of chemicals responsive to detection of the one or more compounds 456, a quantity of the one or more compounds exceeds a threshold level for the volume. The signal 466 may include sensor information, such as location information for the sensor 314, as one example. Additionally, the processor 464 may be used to determine, based on the signal 466, a location of the one or more chemical sensors 314 associated with the signal 466. For example, specific signals 466 may include information to enable correspondence between the signal originator, which may be associated with a location for a particular chemical sensor 314. Thereafter, the one or more processors 464 may be used to provide an indication of a leak and a leak location.

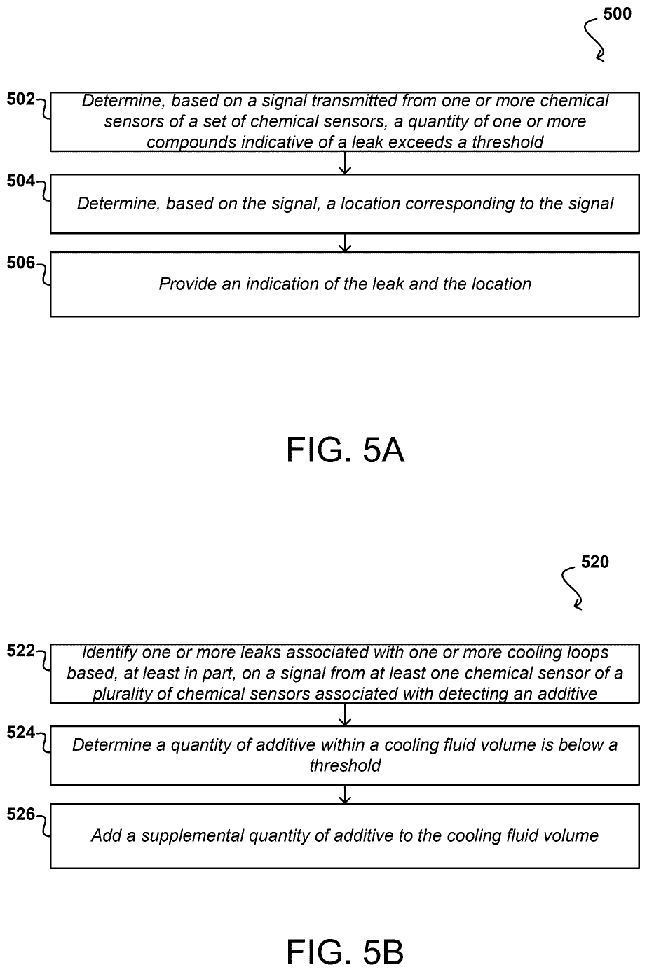

FIG. 5A illustrates an example process 500 for detecting leaks within an area of interest. It should be appreciated that steps for the method may be performed in any order, or in parallel, unless otherwise specifically stated. Moreover, the method may include more or fewer steps. In this example, it is determined that a quantity of one or more compounds indicative of a leak in a cooling fluid system exceeds a threshold 502. The quantity of the one or more compounds may be associated with a signal received from one or more chemical sensors, which may be positioned to detect leaks within a certain area of interest. A location of the signal may be determined 504. For example, the signal may include an identification related to a particular chemical sensor, which may be mapped or otherwise associated with a particular location, such as within a data center. An indication of the leak and the location may then be provided 506. For example, an alarm may be provided to one or more operators to go and investigate the leak.

FIG. 5B illustrates an example process 520 for adjusting an additive quantity within a cooling fluid volume. In this example, one or more leaks may be identified for one or more cooling loops 522. The leaks may be identified based on a signal from at least one chemical sensor that is configured to detect an additive. Based on the signal, it may be determined that a quantity of the additive is below a threshold 524. For example, the signal may be below a desired threshold level, may dissipate below a level too quickly, and/or combinations thereof. As a result, a supplemental quantity of additive may be added to the cooling fluid volume 526.

As discussed, aspects of various approaches presented herein can be lightweight enough to execute on a device such as a client device, such as a personal computer or gaming console, in real time. Such processing can be performed on, or for, content that is generated on, or received by, that client device or received from an external source, such as streaming data or other content received over at least one network. In some instances, the processing and/or determination of this content may be performed by one of these other devices, systems, or entities, then provided to the client device (or another such recipient) for presentation or another such use.

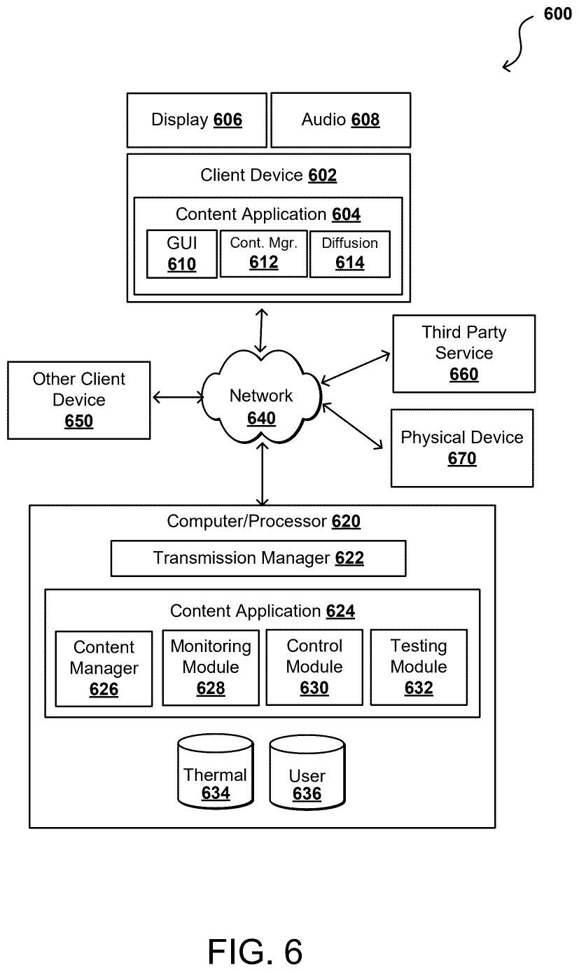

FIG. 6 illustrates an example network configuration 600 of components that can be used to implement aspects of various embodiments, such as to provide, generate, modify, encode, process, fuse, and/or transmit generated image data, calculated measurements, or other such content. In at least one embodiment, a client device 602 can generate or receive data for a session using components of a content application 604 on the client device 602 and data stored locally on that client device. In at least one embodiment, a content application 624 executing on a computer or processor 620 (e.g., a cloud server or control system) may initiate a session associated with at least one client device 602 (e.g., a vehicle or robot), as may use a session manager and user data stored in a user database 636, and can cause content such as liquid coolant or server thermal data to be selected and/or retrieved from a repository 634 to be used by a testing module 632 to calculate one or more performance metrics for a monitoring module 628, which can provide flow data or thermal data to a control module 630 to control a flow or temperature, in an environment where the data is to be used to determine appropriate operation. A content manager 626 may work with at these various modules to perform testing and analysis, and potentially instruct any actions to be taken in response to a performance metric failing to satisfy an operational requirements. At least a portion of this data or instructional content can be transmitted to the client device 602 and/or a physical device 670 using an appropriate transmission manager 622 to send by download, streaming, or another such transmission channel. An encoder may be used to encode and/or compress at least some of this data before transmitting to the client device 602. In at least one embodiment, the client device 602 receiving such content can provide this content to a corresponding content application 604, which may also or alternatively include a graphical user interface 610, a flow monitor module 612, and a control module 614 for use in providing, synthesizing, rendering, compositing, modifying, or using content for presentation, navigation, control, (or other purposes) on or by the client device 602, such as may be transmitted to the physical device 670. In some embodiments, the computer/processor 620 and client device 602 may be able to communicate directly without needing to transmit data over a network 640, in order to avoid issues with latency and availability, etc. A decoder may also be used to decode data received over the network 640 for presentation via client device 602, such as imaging content or performance metrics through a display device 606 and audio, such as corresponding sounds or synthesized speech, through at least one audio playback device 608, such as speakers or headphones. In at least one embodiment, at least some of this content may already be stored on, rendered on, or accessible to client device 602 such that transmission over a network 640 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 620, or user database 636, to the client device 602. In at least one embodiment, at least a portion of this content can be obtained, enhanced, and/or streamed from another source, such as a third party service 660 or other client device 650, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit). In at least one embodiment, portions of this functionality can be performed using multiple computing devices, or multiple processors within one or more computing devices, such as may include a combination of CPUs and GPUs, DPUs, QPUs, a plurality of parallel processing units (PPUs).

In this example, these client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by enabling the client devices to interact with servers that are in closer proximity, while also improving security of resources in the cloud provider environment.

In at least one embodiment, such a system can be used for performing graphical rendering operations. In other embodiments, such a system can be used for other purposes, such as for providing image or video content to test or validate autonomous machine applications, or for performing deep learning operations. In at least one embodiment, such a system can be implemented using an edge device, or may incorporate one or more Virtual Machines (VMs). In at least one embodiment, such a system can be implemented at least partially in a data center or at least partially using cloud computing resources.

### Data Center

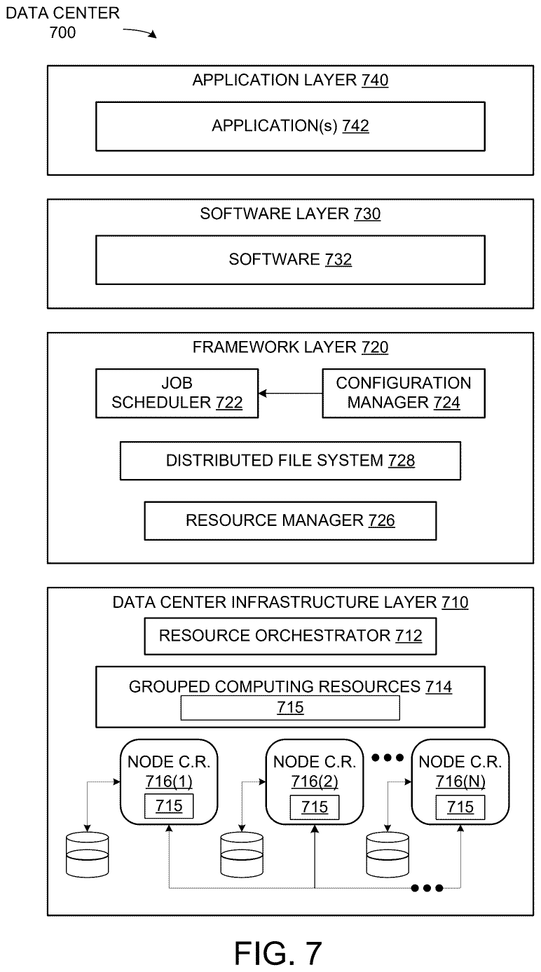

FIG. 7 illustrates an example data center 700, in which at least one embodiment may be used. In at least one embodiment, data center 700 includes a data center infrastructure layer 710, a framework layer 720, a software layer 730, and an application layer 740.

In at least one embodiment, as shown in FIG. 7, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R. s from among node C.R.s 716(1)-716(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 716(1)-716(N) and/or grouped computing resources 714. In at least one embodiment, resource orchestrator 712 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may use distributed file system 728 for large-scale data processing (e.g., “big data”). In at least one embodiment, job scheduler 722 may include a Spark driver to facilitate scheduling of workloads supported by various layers of data center 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resource 814 at data center infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. The one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underused and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, data center may use CPUs, application-specific integrated circuits (ASICs), GPUs, DPU, a network interface controller (NIC), FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 715 are used to perform inferencing and/or training operations associated with one or more embodiments. In at least one embodiment, inference and/or training logic 715 may be used in system FIG. 7 for inferencing or predicting operations based, at least in part, on weight parameters calculated using neural network training operations, neural network functions and/or architectures, or neural network use cases described herein.

In at least one embodiment, data centers may use CPUs, application-specific integrated circuits (ASICs), GPUs, FPGAs, DPUs, QPUs, a plurality of parallel processing units (PPUs), or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU, DPU, QPU, a plurality of parallel processing units (PPUs). A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

Such components can be used in data centers that use liquid cooling systems.

### Computer Systems

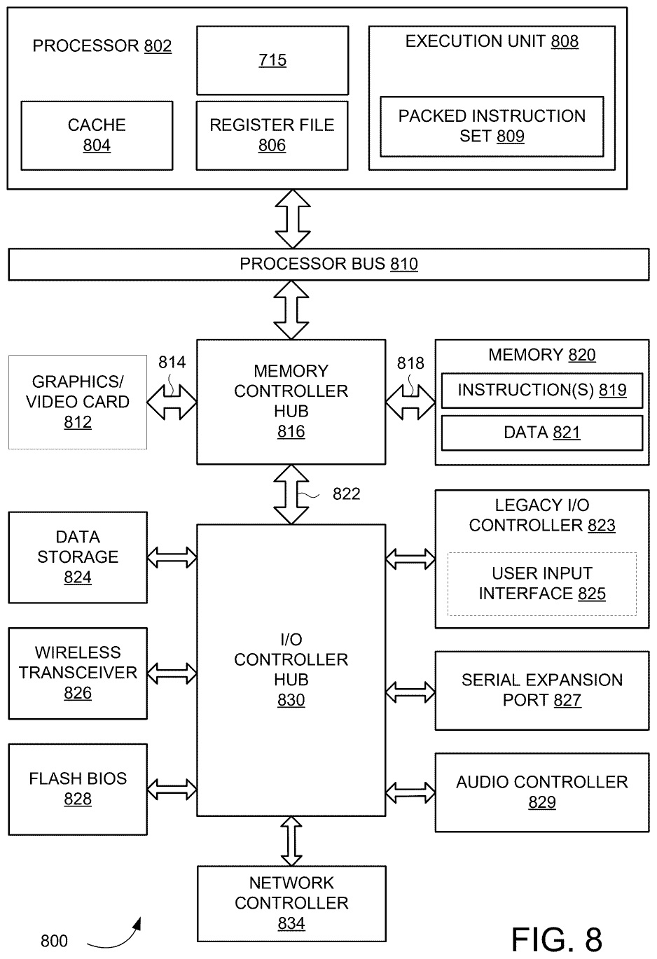

FIG. 8 is a block diagram illustrating an exemplary computer system, which may be a system with interconnected devices and components, a system-on-a-chip (SOC) or some combination thereof 800 formed with a processor that may include execution units to execute an instruction, according to at least one embodiment. In at least one embodiment, computer system 800 may include, without limitation, a component, such as a processor 802 to employ execution units including logic to perform algorithms for process data, in accordance with present disclosure, such as in embodiment described herein. In at least one embodiment, computer system 800 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 800 may execute a version of WINDOWS′ operating system available from Microsoft Corporation of Redmond, Wash., although other operating systems (UNIX and Linux for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 800 may include, without limitation, processor 802 that may include, without limitation, one or more execution units 808 to perform machine learning model training and/or inferencing according to techniques described herein. In at least one embodiment, computer system 800 is a single processor desktop or server system, but in another embodiment computer system 800 may be a multiprocessor system. In at least one embodiment, processor 802 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 802 may be coupled to a processor bus 810 that may transmit data signals between processor 802 and other components in computer system 800.

In at least one embodiment, processor 802 may include, without limitation, a Level 1 (“L1”) internal cache memory (“cache”) 804. In at least one embodiment, processor 802 may have a single internal cache or multiple levels of internal cache. In at least one embodiment, cache memory may reside external to processor 802. Other embodiments may also include a combination of both internal and external caches depending on particular implementation and needs. In at least one embodiment, register file 806 may store different types of data in various registers including, without limitation, integer registers, floating point registers, status registers, and instruction pointer register.

In at least one embodiment, execution unit 808, including, without limitation, logic to perform integer and floating point operations, also resides in processor 802. In at least one embodiment, processor 802 may also include a microcode (“ucode”) read only memory (“ROM”) that stores microcode for certain macro instructions. In at least one embodiment, execution unit 808 may include logic to handle a packed instruction set 809. In at least one embodiment, by including packed instruction set 809 in an instruction set of a general-purpose processor 802, along with associated circuitry to execute instructions, operations used by many multimedia applications may be performed using packed data in a general-purpose processor 802. In one or more embodiments, many multimedia applications may be accelerated and executed more efficiently by using full width of a processor's data bus for performing operations on packed data, which may eliminate need to transfer smaller units of data across processor's data bus to perform one or more operations one data element at a time.

In at least one embodiment, execution unit 808 may also be used in microcontrollers, embedded processors, graphics devices, DSPs, and other types of logic circuits. In at least one embodiment, computer system 800 may include, without limitation, a memory 820. In at least one embodiment, memory 820 may be implemented as a Dynamic Random Access Memory (“DRAM”) device, a Static Random Access Memory (“SRAM”) device, flash memory device, or other memory device. In at least one embodiment, memory 820 may store instruction(s) 819 and/or data 821 represented by data signals that may be executed by processor 802.

In at least one embodiment, system logic chip may be coupled to processor bus 810 and memory 820. In at least one embodiment, system logic chip may include, without limitation, a memory controller hub (“MCH”) 816, and processor 802 may communicate with MCH 816 via processor bus 810. In at least one embodiment, MCH 816 may provide a high bandwidth memory path 818 to memory 820 for instruction and data storage and for storage of graphics commands, data and textures. In at least one embodiment, MCH 816 may direct data signals between processor 802, memory 820, and other components in computer system 800 and to bridge data signals between processor bus 810, memory 820, and a system I/O 822. In at least one embodiment, system logic chip may provide a graphics port for coupling to a graphics controller. In at least one embodiment, MCH 816 may be coupled to memory 820 through a high bandwidth memory path 818 and graphics/video card 812 may be coupled to MCH 816 through an Accelerated Graphics Port (“AGP”) interconnect 814.

In at least one embodiment, computer system 800 may use system I/O 822 that is a proprietary hub interface bus to couple MCH 816 to I/O controller hub (“ICH”) 830. In at least one embodiment, ICH 830 may provide direct connections to some I/O devices via a local I/O bus. In at least one embodiment, local I/O bus may include, without limitation, a high-speed I/O bus for connecting peripherals to memory 820, chipset, and processor 802. Examples may include, without limitation, an audio controller 829, a firmware hub (“flash BIOS”) 828, a wireless transceiver 826, a data storage 824, a legacy I/O controller 823 containing user input and keyboard interface(s) 825, a serial expansion port 827, such as Universal Serial Bus (“USB”), and a network controller 834. Data storage 824 may comprise a hard disk drive, a floppy disk drive, a CD-ROM device, a flash memory device, or other mass storage device.

In at least one embodiment, FIG. 8 illustrates a system, which includes interconnected hardware devices or “chips”, whereas in other embodiments, FIG. 8 may illustrate an exemplary System on a Chip (“SoC”). In at least one embodiment, devices may be interconnected with proprietary interconnects, standardized interconnects (e.g., PCIe) or some combination thereof. In at least one embodiment, one or more components of computer system 800 are interconnected using compute express link (CXL) interconnects.

Inference and/or training logic 715 are used to perform inferencing and/or training operations associated with one or more embodiments. In at least one embodiment, inference and/or training logic 715 may be used in system FIG. 8 for inferencing or predicting operations based, at least in part, on weight parameters calculated using neural network training operations, neural network functions and/or architectures, or neural network use cases described herein.

Such components can be used in data centers that use liquid cooling systems.

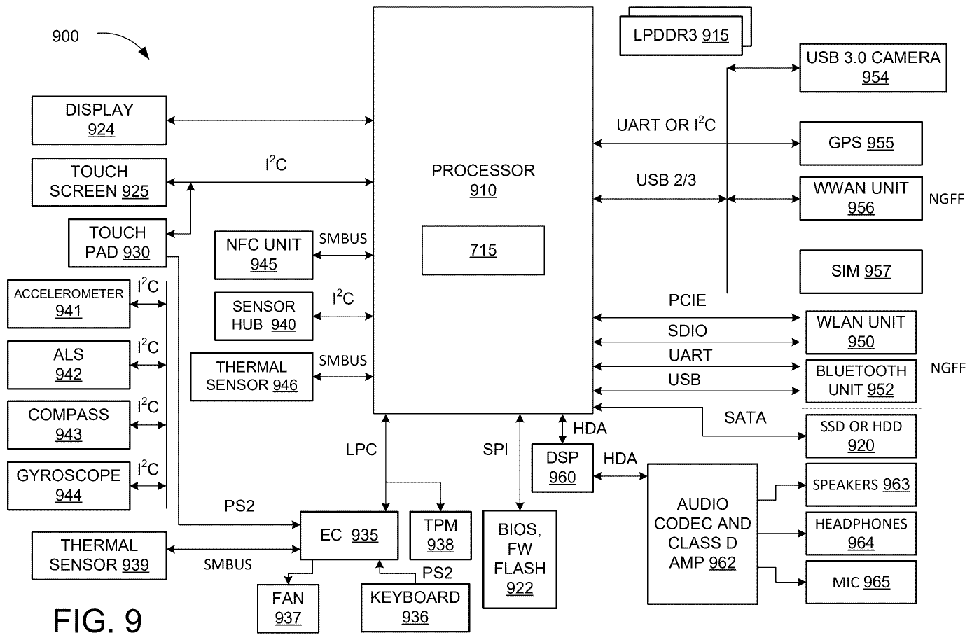

FIG. 9 is a block diagram illustrating an electronic device 900 for utilizing a processor 910, according to at least one embodiment. In at least one embodiment, electronic device 900 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 900 may include, without limitation, processor 910 communicatively coupled to any suitable number or kind of components, peripherals, modules, or devices. In at least one embodiment, processor 910 coupled using a bus or interface, such as a 1° C. bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3), or a Universal Asynchronous Receiver/Transmitter (“UART”) bus. In at least one embodiment, FIG. 9 illustrates a system, which includes interconnected hardware devices or “chips”, whereas in other embodiments, FIG. 9 may illustrate an exemplary System on a Chip (“SoC”). In at least one embodiment, devices illustrated in FIG. 9 may be interconnected with proprietary interconnects, standardized interconnects (e.g., PCIe) or some combination thereof. In at least one embodiment, one or more components of FIG. 9 are interconnected using compute express link (CXL) interconnects.

In at least one embodiment, FIG. 9 may include a display 924, a touch screen 925, a touch pad 930, a Near Field Communications unit (“NFC”) 945, a sensor hub 940, a thermal sensor 946, an Express Chipset (“EC”) 935, a Trusted Platform Module (“TPM”) 938, BIOS/firmware/flash memory (“BIOS, FW Flash”) 922, a DSP 960, a drive 920 such as a Solid State Disk (“SSD”) or a Hard Disk Drive (“HDD”), a wireless local area network unit (“WLAN”) 950, a Bluetooth unit 952, a Wireless Wide Area Network unit (“WWAN”) 956, a Global Positioning System (GPS) 955, a camera (“USB 3.0 camera”) 954 such as a USB 3.0 camera, and/or a Low Power Double Data Rate (“LPDDR”) memory unit (“LPDDR3”) 915 implemented in, for example, LPDDR3 standard. These components may each be implemented in any suitable manner.

In at least one embodiment, other components may be communicatively coupled to processor 910 through components discussed above. In at least one embodiment, an accelerometer 941, Ambient Light Sensor (“ALS”) 942, compass 943, and a gyroscope 944 may be communicatively coupled to sensor hub 940. In at least one embodiment, thermal sensor 939, a fan 937, a keyboard 936, and a touch pad 930 may be communicatively coupled to EC 935. In at least one embodiment, speakers 963, headphones 964, and microphone (“mic”) 965 may be communicatively coupled to an audio unit (“audio codec and class d amp”) 962, which may in turn be communicatively coupled to DSP 960. In at least one embodiment, audio unit 964 may include, for example and without limitation, an audio coder/decoder (“codec”) and a class D amplifier. In at least one embodiment, SIM card (“SIM”) 957 may be communicatively coupled to WWAN unit 956. In at least one embodiment, components such as WLAN unit 950 and Bluetooth unit 952, as well as WWAN unit 956 may be implemented in a Next Generation Form Factor (“NGFF”).

Inference and/or training logic 715 are used to perform inferencing and/or training operations associated with one or more embodiments. In at least one embodiment, inference and/or training logic 715 may be used in system FIG. 9 for inferencing or predicting operations based, at least in part, on weight parameters calculated using neural network training operations, neural network functions and/or architectures, or neural network use cases described herein.

Such components can be used in data centers that use liquid cooling systems.

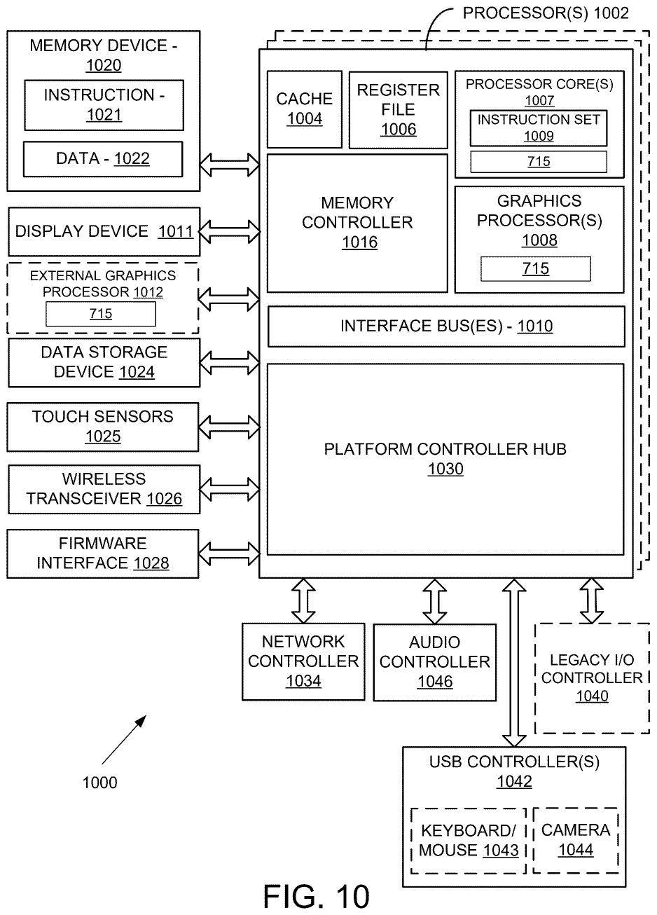

FIG. 10 is a block diagram of a processing system, according to at least one embodiment. In at least one embodiment, system 1000 includes one or more processor(s) 1002 and one or more graphics processor(s) 1008, and may be a single processor desktop system, a multiprocessor workstation system, or a server system having a large number of processor(s) 1002 or processor core(s) 1007. In at least one embodiment, system 1000 is a processing platform incorporated within a system-on-a-chip (SoC) integrated circuit for use in mobile, handheld, or embedded devices.

In at least one embodiment, system 1000 can include, or be incorporated within a server-based gaming platform, a game console, including a game and media console, a mobile gaming console, a handheld game console, or an online game console. In at least one embodiment, system 1000 is a mobile phone, smart phone, tablet computing device or mobile Internet device. In at least one embodiment, processing system 1000 can also include, couple with, or be integrated within a wearable device, such as a smart watch wearable device, smart eyewear device, augmented reality device, or virtual reality device. In at least one embodiment, processing system 1000 is a television or set top box device having one or more processor(s) 1002 and a graphical interface generated by one or more graphics processor(s) 1008.

In at least one embodiment, one or more processor(s) 1002 each include one or more processor core(s) 1007 to process instructions which, when executed, perform operations for system and user software. In at least one embodiment, each of one or more processor core(s) 1007 is configured to process a specific instruction set 1009. In at least one embodiment, instruction set 1009 may facilitate Complex Instruction Set Computing (CISC), Reduced Instruction Set Computing (RISC), or computing via a Very Long Instruction Word (VLIW). In at least one embodiment, processor core(s) 1007 may each process a different instruction set 1009, which may include instructions to facilitate emulation of other instruction sets. In at least one embodiment, processor core(s) 1007 may also include other processing devices, such a Digital Signal Processor (DSP).

In at least one embodiment, processor(s) 1002 includes cache memory 1004. In at least one embodiment, processor(s) 1002 can have a single internal cache or multiple levels of internal cache. In at least one embodiment, cache memory is shared among various components of processor(s) 1002. In at least one embodiment, processor(s) 1002 also uses an external cache (e.g., a Level-3 (L3) cache or Last Level Cache (LLC)) (not shown), which may be shared among processor core(s) 1007 using known cache coherency techniques. In at least one embodiment, register file 1006 is additionally included in processor(s) 1002 which may include different types of registers for storing different types of data (e.g., integer registers, floating point registers, status registers, and an instruction pointer register). In at least one embodiment, register file 1006 may include general-purpose registers or other registers.

In at least one embodiment, one or more processor(s) 1002 are coupled with one or more interface bus(es) 1010 to transmit communication signals such as address, data, or control signals between processor(s) 1002 and other components in system 1000. In at least one embodiment, interface bus(es) 1010, in one embodiment, can be a processor bus, such as a version of a Direct Media Interface (DMI) bus. In at least one embodiment, interface bus(es) 1010 is not limited to a DMI bus, and may include one or more Peripheral Component Interconnect buses (e.g., PCI, PCI Express), memory busses, or other types of interface busses. In at least one embodiment processor(s) 1002 include an integrated memory controller 1016 and a platform controller hub 1030. In at least one embodiment, memory controller 1016 facilitates communication between a memory device and other components of system 1000, while platform controller hub (PCH) 1030 provides connections to I/O devices via a local I/O bus.

In at least one embodiment, memory device 1020 can be a dynamic random access memory (DRAM) device, a static random access memory (SRAM) device, flash memory device, phase-change memory device, or some other memory device having suitable performance to serve as process memory. In at least one embodiment memory device 1020 can operate as system memory for system 1000, to store data 1022 and instruction 1021 for use when one or more processor(s) 1002 executes an application or process. In at least one embodiment, memory controller 1016 also couples with an optional external graphics processor 1012, which may communicate with one or more graphics processor(s) 1008 in processor(s) 1002 to perform graphics and media operations. In at least one embodiment, a display device 1011 can connect to processor(s) 1002. In at least one embodiment display device 1011 can include one or more of an internal display device, as in a mobile electronic device or a laptop device or an external display device attached via a display interface (e.g., DisplayPort, etc.). In at least one embodiment, display device 1011 can include a head mounted display (HMD) such as a stereoscopic display device for use in virtual reality (VR) applications or augmented reality (AR) applications.

In at least one embodiment, platform controller hub 1030 enables peripherals to connect to memory device 1020 and processor(s) 1002 via a high-speed I/O bus. In at least one embodiment, I/O peripherals include, but are not limited to, an audio controller 1046, a network controller 1034, a firmware interface 1028, a wireless transceiver 1026, touch sensors 1025, a data storage device 1024 (e.g., hard disk drive, flash memory, etc.). In at least one embodiment, data storage device 1024 can connect via a storage interface (e.g., SATA) or via a peripheral bus, such as a Peripheral Component Interconnect bus (e.g., PCI, PCI Express). In at least one embodiment, touch sensors 1025 can include touch screen sensors, pressure sensors, or fingerprint sensors. In at least one embodiment, wireless transceiver 1026 can be a Wi-Fi transceiver, a Bluetooth transceiver, or a mobile network transceiver such as a 3G, 4G, or Long Term Evolution (LTE) transceiver. In at least one embodiment, firmware interface 1028 enables communication with system firmware, and can be, for example, a unified extensible firmware interface (UEFI). In at least one embodiment, network controller 1034 can enable a network connection to a wired network. In at least one embodiment, a high-performance network controller (not shown) couples with interface bus(es) 1010. In at least one embodiment, audio controller 1046 is a multi-channel high definition audio controller. In at least one embodiment, system 1000 includes an optional legacy I/O controller 1040 for coupling legacy (e.g., Personal System 2 (PS/2)) devices to system. In at least one embodiment, platform controller hub 1030 can also connect to one or more Universal Serial Bus (USB) controller(s) 1042 connect input devices, such as keyboard and mouse 1043 combinations, a camera 1044, or other USB input devices.

In at least one embodiment, an instance of memory controller 1016 and platform controller hub 1030 may be integrated into a discreet external graphics processor, such as external graphics processor 1012. In at least one embodiment, platform controller hub 1030 and/or memory controller 1016 may be external to one or more processor(s) 1002. For example, in at least one embodiment, system 1000 can include an external memory controller 1016 and platform controller hub 1030, which may be configured as a memory controller hub and peripheral controller hub within a system chipset that is in communication with processor(s) 1002.

Inference and/or training logic 715 are used to perform inferencing and/or training operations associated with one or more embodiments. In at least one embodiment, portions or all of inference and/or training logic 715 may be incorporated into graphics processor(s) 1008. For example, in at least one embodiment, training and/or inferencing techniques described herein may use one or more of ALUs embodied in a graphics processor. In at least one embodiment, weight parameters may be stored in on-chip or off-chip memory and/or registers (shown or not shown) that configure ALUs of a graphics processor to perform one or more machine learning algorithms, neural network architectures, use cases, or training techniques described herein.

Such components can be used in data centers that use liquid cooling systems.

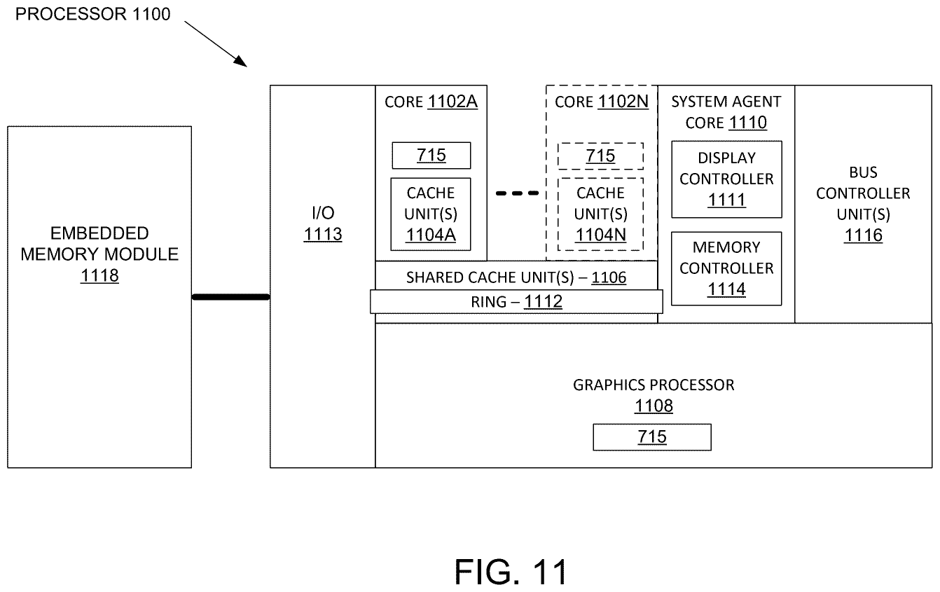

FIG. 11 is a block diagram of a processor 1100 having one or more processor core(s) 1102A-1102N, an integrated memory controller 1114, and an integrated graphics processor 1108, according to at least one embodiment. In at least one embodiment, processor 1100 can include additional cores up to and including additional core 1102N represented by dashed lined boxes. In at least one embodiment, each of processor core(s) 1102A-1102N includes one or more internal cache unit(s) 1104A-1104N. In at least one embodiment, each processor core also has access to one or more shared cached unit(s) 1106.

In at least one embodiment, internal cache unit(s) 1104A-1104N and shared cache unit(s) 1106 represent a cache memory hierarchy within processor 1100. In at least one embodiment, cache unit(s) 1104A-1104N may include at least one level of instruction and data cache within each processor core and one or more levels of shared mid-level cache, such as a Level 2(L2 ), Level 3 (L3), Level 4 (L4 ), or other levels of cache, where a highest level of cache before external memory is classified as an LLC. In at least one embodiment, cache coherency logic maintains coherency between various cache unit(s) 1106 and 1104A-1104N.

In at least one embodiment, processor 1100 may also include a set of one or more bus controller unit(s) 1116 and a system agent core 1110. In at least one embodiment, one or more bus controller unit(s) 1116 manage a set of peripheral buses, such as one or more PCI or PCI express buses. In at least one embodiment, system agent core 1110 provides management functionality for various processor components. In at least one embodiment, system agent core 1110 includes one or more integrated memory controllers 1114 to manage access to various external memory devices (not shown).

In at least one embodiment, one or more of processor core(s) 1102A-1102N include support for simultaneous multi-threading. In at least one embodiment, system agent core 1110 includes components for coordinating and operating processor core(s) 1102A-1102N during multi-threaded processing. In at least one embodiment, system agent core 1110 may additionally include a power control unit (PCU), which includes logic and components to regulate one or more power states of processor core(s) 1102A-1102N and graphics processor 1108.

In at least one embodiment, processor 1100 additionally includes graphics processor 1108 to execute graphics processing operations. In at least one embodiment, graphics processor 1108 couples with shared cache unit(s) 1106, and system agent core 1110, including one or more integrated memory controllers 1114. In at least one embodiment, system agent core 1110 also includes a display controller 1111 to drive graphics processor output to one or more coupled displays. In at least one embodiment, display controller 1111 may also be a separate module coupled with graphics processor 1108 via at least one interconnect, or may be integrated within graphics processor 1108.

In at least one embodiment, a ring based interconnect unit 1112 is used to couple internal components of processor 1100. In at least one embodiment, an alternative interconnect unit may be used, such as a point-to-point interconnect, a switched interconnect, or other techniques. In at least one embodiment, graphics processor 1108 couples with ring based interconnect unit 1112 via an I/O link 1113.

In at least one embodiment, I/O link 1113 represents at least one of multiple varieties of I/O interconnects, including an on package I/O interconnect which facilitates communication between various processor components and a high-performance embedded memory module 1118, such as an eDRAM module. In at least one embodiment, each of processor core(s) 1102A-1102N and graphics processor 1108 use embedded memory modules 1118 as a shared Last Level Cache.

In at least one embodiment, processor core(s) 1102A-1102N are homogenous cores executing a common instruction set architecture. In at least one embodiment, processor core(s) 1102A-1102N are heterogeneous in terms of instruction set architecture (ISA), where one or more of processor core(s) 1102A-1102N execute a common instruction set, while one or more other cores of processor core(s) 1102A-1102N executes a subset of a common instruction set or a different instruction set. In at least one embodiment, processor core(s) 1102A-1102N are heterogeneous in terms of microarchitecture, where one or more cores having a relatively higher power consumption coupled with one or more power cores having a lower power consumption. In at least one embodiment, processor 1100 can be implemented on one or more chips or as an SoC integrated circuit.

Inference and/or training logic 715 are used to perform inferencing and/or training operations associated with one or more embodiments. In at least one embodiment, portions or all of inference and/or training logic 715 may be incorporated into processor 1100. For example, in at least one embodiment, training and/or inferencing techniques described herein may use one or more of ALUs embodied in graphics processor 1108, processor core(s) 1102A-1102N, or other components in FIG. 11. In at least one embodiment, weight parameters may be stored in on-chip or off-chip memory and/or registers (shown or not shown) that configure ALUs of graphics processor 1100/1108 to perform one or more machine learning algorithms, neural network architectures, use cases, or training techniques described herein.

Such components can be used in data centers that use liquid cooling systems.

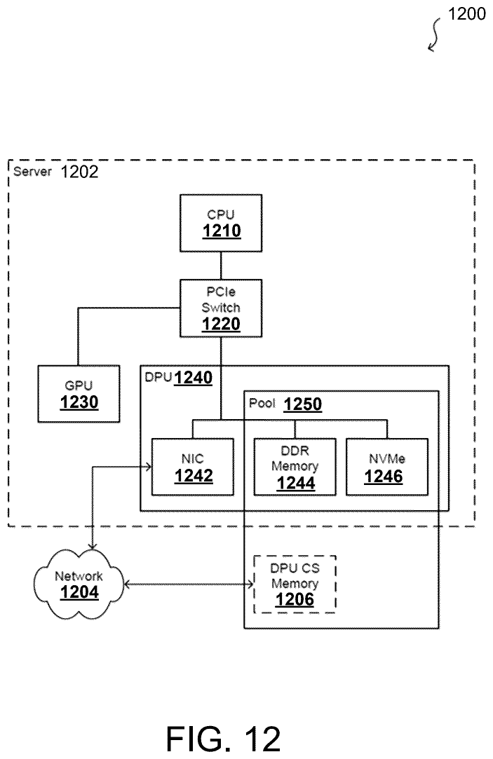

FIG. 12 illustrates an example computing environment 1200 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1200 may include a server 1202 which may be used to perform HPC workloads, such as AI training or machine learning model training. In an embodiment, the server 1202 may be an application instance or a compute node. The server 1202 may include a CPU 1210 associated with a switch 1220, such as a peripheral component interconnect express (PCIe) switch, which may control at least some data transmission over communication paths interconnecting various components. In an embodiment, the CPU 110 may include a root complex processor.

The PCIe switch 1220 may also be associated with a GPU 1230 and a DPU 1240, and may transmit data between at least some of the CPU 1210, the GPU 1230, the DPU 1240, and other components. In an embodiment, the PCIe switch 1220 may be associated with more than one GPU or more than one DPU. In another embodiment, the PCIe switch 1220 may be located within the DPU 1240. The PCIe switch 1220 may manage the transfer of at least some data between the CPU 1210, the GPU 1230, and the DPU 1240. In another embodiment, the number of GPUs associated with the PCIe switch 1220 may be equal to the number of DPUs associated with the PCIe switch 1220. In at least one embodiment, the server 1202 may include, without limitation, any number of the CPUs 110, the PCIe switches 1220, the GPUs 1230, and/or the DPUs 1240, in any combination. For example, in at least one embodiment, server 1202 could include eight, sixteen, thirty-two, and/or more GPUs 1230. In at least one embodiment, communication paths interconnecting various components, including but not limited to the CPU 1210, the PCIe switch 1220, the GPU 1230, and the DPU 1240, in FIG. 12 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1240 may include a network interface card (NIC) 1242, a DDR memory 1244, and a non-volatile memory express (NVMe) device 1246. The NIC 1242 may be able to interface with a network 1204, which may also interface with additional NVMe devices available to the DPU 1240, such as over fabric. In an embodiment, the DPU 1240 may not include the NVMe device 1246. In another embodiment, the NVMe device 1246 may be located on the server 1202 and not on the DPU 1240. In yet another embodiment, the computing environment 1200 may include more than one of the NVMe device 1246, such as a first NVMe device in the DPU 1240 and a second first NVMe device on the server 1202 an associated directly with the PCIe switch 1220. In an embodiment, the DPU 1240 may not include the DDR memory 1244 and may include a computational storage services (CSS) in place of, or in addition to, the DDR memory 1244. For example, computing environment 1200 may include DPU computational storage (CS) memory 1206 available to the DPU 1240 as part of the CSS. The network 1204 may be able to interface with the DPU CS memory 1206 through the NIC 1242, according to any suitable interface protocol, such as remote direct memory access (RDMA) over Ethernet, InfiniBand, Fiber Channel, etc.

The total memory of the computing environment 1200 available for data storage may be expanded through the use of the DPU 1240 on nodes of the system. The DPU 1240 may have access to a pool 1250 of memory already available to the server 1202, such as double data rate (DDR) memory, on-board NVMe devices, NVMe devices over fabric, and CS. The pool 1250 of memory may include at least one of the DDR memory 1244, NVMe 1246, and the DPU CS memory 1206. The DPU 1240 may also be able to access the available memory of other DPUs as part of the pool 1250, and other DPUs may be able to access the available memory of DPU 1240, such as the pool 1250. This available memory can be accessed and utilized for data storage, without the addition of compute resources, such as compute nodes, which would be required using other solutions. The available pool 1250 accessible to the DPU 1240 may be provisioned for the server 1202 to expand the total memory available for data storage, such as to reduce the data storage load on the CPU 1210 or the GPU 1230, which can instead increase the utilization of their memory for processing. For example, during training of an AI, the model states, residual states, activation functions, and checkpoints can be stored, or offloaded, on the pool 1250 accessible to the DPU 1240.

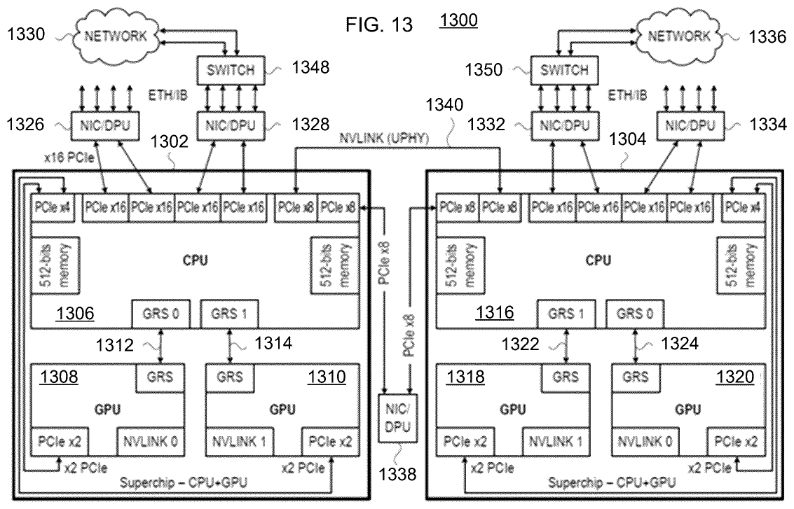

FIG. 13 is a block diagram that schematically illustrates a computing system 1300, e.g., a data center or a High-Performance Computing (HPC) cluster, in accordance with an embodiment that is described herein. System 1300 comprises a plurality of subsystems, e.g. multiple processing devices coupled to each other, multiple network devices, and multiple networks, according to at least one embodiment. Computing system 1300 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1300 and to one or more external networks 1330, 1336. In the present example, system 1300 comprises a packet switch 1348 that connects NIC/DPU 1328 to network 1330, and a packet switch 1350 that connects NIC/DPU 1332 to network 1336.

The coupling of processing devices through NVLink allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1300 can include one or more CPUs and one or more GPUs.

FIG. 13 also demonstrates an example architecture of a multi-GPU architecture. As illustrated in the figure, computing system 1300 includes a processing device 1302 with a multi-GPU architecture. In particular, processing device 1302 may be a system-on-chip and includes multiple subsystems such as a CPU 1306, a GPU 1308, and a GPU 1310. CPU 1306 can be coupled to GPU 1308 via a die-to-die (D2D) or chip-to-chip (C2C) interconnect 1312, such as a Ground-Referenced Signaling interconnect (GRS interconnect). CPU 1306 can be coupled to GPU 1310 via a D2D or C2C interconnect 1314. CPU 1306 can also couple to GPU 1308 and GPU 1310 via PCIe interconnects.

CPU 1306 can be coupled to one or more NICs or DPUs, which are coupled to one or more networks. For example, as illustrated in FIG. 13, CPU 1306 is coupled to a first NIC/DPU 1326, which is coupled to a network 1330. CPU 1306 is also coupled to a second NIC/DPU 1328, which is coupled to network 1330 via switch 1348. NIC/DPU 1326 and NIC/DPU 1328 can be coupled to network 1330 over Ethernet (ETH), NVLINK or InfiniBand (IB) connections, for example.

Computing system 1300 also includes a processing device 1304 with a multi-GPU architecture. In particular, processing device 1304 includes multiple subsystems including a CPU 1316, a GPU 1318, and a GPU 1320. CPU 1316 can be coupled to GPU 1318 via an D2D or C2C interconnect 1322. CPU 1316 can be coupled to GPU 1320 via a D2D or C2C interconnect 1324. CPU 1316 can also couple to GPU 1318 and GPU 1320 via PCIe interconnects. CPU 1316 can be coupled to one or more NICs or DPUs, which are coupled to one or more networks. For example, as illustrated in FIG. 13, CPU 1316 is coupled to a first NIC/DPU 1332, which is coupled to a network 1336. CPU 1316 is also coupled to a second NIC/DPU 1334, which is coupled to network 1336 via switch 1350. NIC/DPU 1332 and NIC/DPU 1334 can be coupled to network 1336 over Ethernet (ETH), NVLINK or InfiniBand (IB) connections.

In at least one embodiment, processing device 1302 and processing device 1304 can communication with each other via a NIC/DPU 1338, such as over PCIe interconnects. Processing device 1302 and processing device 1304 can also communicate with each other over a high-bandwidth communication interconnects 1340, such as an NVLink interconnect or other high-speed interconnects. The packet switches in FIG. 13 may comprise, for example, Nvidia Quantum-2 switches. The NICs/DPUs in the figure may comprise, for example, Nvidia Bluefield DPUs.

In various embodiments, any of the network devices of system 1300, e.g., any of NICs/DPUs 1326, 1328, 1332, 1334 and 1338, and/or any of switches 1348 and 1350, may use ILI packets in accordance with the techniques described herein.

Various embodiments can be described by the following clauses:
1. A leak detection system, comprising:
   one or more chemical sensors to be positioned within a volume associated with a processing unit rack, the one or more chemical sensors to detect one or more compounds injected into a cooling fluid circulated through a cooling loop associated with one or more processing units of the processing unit rack; and
   a processor having one or more circuits to:
   determine, based on a signal transmitted from the one or more chemical sensors responsive to detection of the one or more compounds, a quantity of the one or more compounds exceeds a threshold level for the volume;
   determine, based on the signal, a location of the one or more chemical sensors associated with the signal; and
   provide an indication of a leak and a leak location.
2. The leak detection system of clause 1, wherein the one or more chemical sensors comprise at least one of an electrochemical sensor, a catalytic sensor, an oxidative sensor, a semiconductor sensor, a photosensitive sensor, an infrared sensor, an ultrasonic sensor, or a holographic sensor.
3. The leak detection system of clause 1, wherein the volume is at least one of a rack enclosure, a rack tray, a hot isle, or a cold isle.
4. The leak detection system of clause 1, wherein the one or more compounds maintain a cooling capacity of the cooling fluid above a threshold limit.
5. The leak detection system of clause 1, wherein the one or more compounds are non-corrosive.
6. The leak detection system of clause 1, wherein each chemical sensor of the one or more of chemical sensors is positioned to monitor a different sub-volume of the volume.
7. The leak detection system of clause 1, wherein a first detectable quantity of the one or more compounds is less than a second detectable quantity of the cooling fluid associated with one or more additional leak sensors associated with the volume.
8. The leak detection system of clause 1, wherein the volume is selected based at least in part on an air flow rate associated with and circulating through the volume,.
9. A system, comprising:
   an enclosure to store one or more processing units in a plurality of racks;
   one or more chemical sensors to detect a threshold quantity of an additive within a volume of the enclosure;
   a cooling fluid system to provide a cooling fluid to remove heat from the one or more processing units, the cooling fluid system including one or more cooling loops associated with individual racks of the plurality of racks;
   an injection system to add a metered quantity of the additive to the cooling fluid; and
   a controller to:
   identify one or more leaks associated with the one or more cooling loops based, at least in part, on a signal from at least one chemical sensor of the one or more chemical sensors associated with detection of the additive within the volume;
   determine a quantity of additive within a cooling fluid volume is below a threshold; and
   responsive to the determination, add a supplemental quantity of additive to the cooling fluid volume.
10. The system of clause 9, further comprising:
   an additive meter; and
   an additive mover, wherein the additive mover injects the supplemental quantity of additive into the cooling fluid.
11. The system of clause 9, wherein the one or more chemical sensors comprise at least one of an electrochemical sensor, a catalytic sensor, an oxidative sensor, a semiconductor sensor, a photosensitive sensor, an infrared sensor, an ultrasonic sensor, or a holographic sensor.
12. The system of clause 9, wherein the additive maintains a cooling capacity of the cooling fluid above a cooling threshold.
13. The system of clause 9, wherein the threshold is at least one of a mass of additive, a volume of additive, or a percentage of additive.
14. The system of clause 9, wherein the additive is an odorant and the odorant is detectable using the one or more chemical sensors or by a human operator.
15. The system of clause 9, wherein the volume includes a plurality of sub-volumes comprising at least one of a manifold inlet flow connection or a cooling loop outlet flow connection.

16. The system of clause 9, wherein the controller is further configured to:
determine an air flow rate associated with the volume;
determine a quantity of the signal; and
determine a leak indicator based, at least in part, on the air flow rate and the quantity.
17. A leak detector comprising:
   a first sensor to detect a cooling liquid additive in an area;
   a second sensor to detect a quantity of the additive in the area; and
   a processor having one or more circuits to:
   receive the detections of the first sensor and the second sensor;
   determine, based on the detections of the first sensor and the second sensor, that the quantity of the additive in the area exceeds a threshold amount for the area;
   locate the first sensor and second sensor within the area; and
   provide an indication of a leak and a leak location.
18. The leak detector of clause 17, wherein the first sensor is arranged at a connection associated with a cooling loop within the area and the second sensor is arranged within a drip tray axially lower than the connection.
19. The leak detector of clause 17, wherein the first sensor comprises at least one of an electrochemical sensor, a catalytic sensor, an oxidative sensor, a semiconductor sensor, a photosensitive sensor, an infrared sensor, an ultrasonic sensor, or a holographic sensor.
20. The leak detector of clause 19, wherein the second sensor is a different type of sensor than the first sensor.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A leak detection system, comprising:
one or more chemical sensors to be positioned within a volume associated with a processing unit rack, the one or more chemical sensors to detect one or more compounds injected into a cooling fluid circulated through a cooling loop associated with one or more processing units of the processing unit rack; and
a processor having one or more circuits to:
determine, based on a signal transmitted from the one or more chemical sensors responsive to detection of the one or more compounds, a quantity of the one or more compounds exceeds a threshold level for the volume;
determine, based on the signal, a location of the one or more chemical sensors associated with the signal; and
provide an indication of a leak and a leak location.

2. The leak detection system of claim 1, wherein the one or more chemical sensors comprise at least one of an electrochemical sensor, a catalytic sensor, an oxidative sensor, a semiconductor sensor, a photosensitive sensor, an infrared sensor, an ultrasonic sensor, or a holographic sensor.

3. The leak detection system of claim 1, wherein the volume is at least one of a rack enclosure, a rack tray, a hot isle, or a cold isle.

4. The leak detection system of claim 1, wherein the one or more compounds maintain a cooling capacity of the cooling fluid above a threshold limit.

5. The leak detection system of claim 1, wherein the one or more compounds are non-corrosive.

6. The leak detection system of claim 1, wherein each chemical sensor of the one or more of chemical sensors is positioned to monitor a different sub-volume of the volume.

7. The leak detection system of claim 1, wherein a first detectable quantity of the one or more compounds is less than a second detectable quantity of the cooling fluid associated with one or more additional leak sensors associated with the volume.

8. The leak detection system of claim 1, wherein the volume is selected based at least in part on an air flow rate associated with and circulating through the volume,.

9. A system, comprising:
an enclosure to store one or more processing units in a plurality of racks;
one or more chemical sensors to detect a threshold quantity of an additive within a volume of the enclosure;
a cooling fluid system to provide a cooling fluid to remove heat from the one or more processing units, the cooling fluid system including one or more cooling loops associated with individual racks of the plurality of racks;
an injection system to add a metered quantity of the additive to the cooling fluid; and
a controller to:
identify one or more leaks associated with the one or more cooling loops based, at least in part, on a signal from at least one chemical sensor of the one or more chemical sensors associated with detection of the additive within the volume;
determine a quantity of additive within a cooling fluid volume is below a threshold; and
responsive to the determination, add a supplemental quantity of additive to the cooling fluid volume.

10. The system of claim 9, further comprising:
an additive meter; and
an additive mover, wherein the additive mover injects the supplemental quantity of additive into the cooling fluid.

11. The system of claim 9, wherein the one or more chemical sensors comprise at least one of an electrochemical sensor, a catalytic sensor, an oxidative sensor, a semiconductor sensor, a photosensitive sensor, an infrared sensor, an ultrasonic sensor, or a holographic sensor.

12. The system of claim 9, wherein the additive maintains a cooling capacity of the cooling fluid above a cooling threshold.

13. The system of claim 9, wherein the threshold is at least one of a mass of additive, a volume of additive, or a percentage of additive.

14. The system of claim 9, wherein the additive is an odorant and the odorant is detectable using the one or more chemical sensors or by a human operator.

15. The system of claim 9, wherein the volume includes a plurality of sub-volumes comprising at least one of a manifold inlet flow connection or a cooling loop outlet flow connection.

16. The system of claim 9, wherein the controller is further configured to:
determine an air flow rate associated with the volume;
determine a quantity of the signal; and
determine a leak indicator based, at least in part, on the air flow rate and the quantity.

17. A leak detector comprising:
a first sensor to detect a cooling liquid additive in an area;
a second sensor to detect a quantity of the additive in the area; and
a processor having one or more circuits to:
receive the detections of the first sensor and the second sensor;
determine, based on the detections of the first sensor and the second sensor, that the quantity of the additive in the area exceeds a threshold amount for the area;
locate the first sensor and second sensor within the area; and
provide an indication of a leak and a leak location.

18. The leak detector of claim 17, wherein the first sensor is arranged at a connection associated with a cooling loop within the area and the second sensor is arranged within a drip tray axially lower than the connection.

19. The leak detector of claim 17, wherein the first sensor comprises at least one of an electrochemical sensor, a catalytic sensor, an oxidative sensor, a semiconductor sensor, a photosensitive sensor, an infrared sensor, an ultrasonic sensor, or a holographic sensor.

20. The leak detector of claim 19, wherein the second sensor is a different type of sensor than the first sensor.
